(19) United States
(12) Patent Application Publication
(10) Pub. No.: US 2026/0354165 A1
(43) Pub. Date: Nov. 5, 2026

(54) INTEGRATED CIRCUIT INCLUDING SOURCE/DRAIN CONTACTS

(71) Applicant: SAMSUNG ELECTRONICS CO., LTD., Suwon-si (KR)

(72) Inventors: Huijae LIM, Suwon-si (KR); Jaeha LEE, Suwon-si (KR)

(73) Assignee: SAMSUNG ELECTRONICS CO., LTD., Suwon-si (KR)

(21) Appl. No.: 19/443,600

(22) Filed: Jan. 8, 2026

(30) Foreign Application Priority Data
Apr. 22, 2025 (KR) 10-2025-0052577

(51) Int. Cl. H10W 20/41; H10D 30/00; H10D 30/01; H10D 30/43; H10D 84/01; H10D 84/83; H10W 20/40; H10W 20/42; H10W 20/43

(52) U.S. Cl. CPC H10W 20/435; H10D 30/43; H10D 30/502; H10D 84/832; H10W 20/422; H10W 20/427; H10W 20/43; H10W 20/495; H10D 30/014; H10D 30/019; H10D 84/0149

(57) ABSTRACT

An integrated circuit includes: a first active region extending in a first direction on a substrate, wherein the first active region has a first width in a second direction; a first source/drain contact extending in the second direction above the first active region, wherein the first source/drain contact has a first length in the second direction; a second source/drain contact extending in the second direction above the first active region, wherein the second source/drain contact has a second length in the second direction; and a first gate line extending in the second direction between the first source/drain contact and the second source/drain contact. A length in the second direction of a first overlap region between the first source/drain contact and the first active region is greater than a length in the second direction of a second overlap region between the second source/drain contact and the first active region.

### CROSS-REFERENCE TO RELATED APPLICATION

This application claims priority under 35 U.S.C. § 119 to Korean Patent Application No. 10-2025-0052577, filed on Apr. 22, 2025, in the Korean Intellectual Property Office, the disclosure of which is incorporated by reference herein in its entirety.

### BACKGROUND

The present disclosure relates to an integrated circuit, and more particularly, to an integrated circuit including source/drain contacts having different lengths.

With increasing demands for compact, multifunctional, and high-performance electronic products, there is a growing need for highly integrated and high-capacity integrated circuit devices. In order to satisfy these requirements, there is a need to improve the degree of integration of integrated circuits. For example, it is possible to reduce the total area of an integrated circuit by reducing a cell height. However, as the cell height decreases, the size of active regions, contacts, or vias also decreases, which may cause a degradation in cell performance. In particular, depending on the size of a contact, the resistance or capacitance of the contact may be affected. Also, this may adversely affect the performance and operating speed of circuits.

### SUMMARY

One or more embodiments provide an integrated circuit including source/drain contacts having different lengths depending on the characteristics of a corresponding net.

According to an aspect of an embodiment, an integrated circuit includes: a first active region extending in a first direction on a substrate, wherein the first active region has a first width in a second direction, and the second direction intersects the first direction; a first source/drain contact extending in the second direction above the first active region, wherein the first source/drain contact is connected to a power line for supplying power, and has a first length in the second direction; a second source/drain contact extending in the second direction above the first active region, wherein the second source/drain contact is connected to a signal line for transmitting a signal, and has a second length in the second direction; and a first gate line extending in the second direction between the first source/drain contact and the second source/drain contact. A length in the second direction of a first overlap region between the first source/drain contact and the first active region is greater than a length in the second direction of a second overlap region between the second source/drain contact and the first active region.

According to another aspect of an embodiment, an integrated circuit includes: a first active region extending in a first direction on a substrate, wherein the first active region has having a first width in a second direction intersecting the first direction; a front-side wiring layer above a front side of the substrate, wherein the front-side wiring layer includes a signal line for transmitting a signal; a backside wiring layer on a backside of the substrate, wherein the backside wiring layer includes a power line for supplying power; a first source/drain contact extending in the second direction above the first active region, wherein the first source/drain contact is connected to the signal line, and has a first length less than the first width of the first active region in the second direction; and a backside contact on the power line, wherein the backside contact passes through the substrate in a vertical direction, is connected to the first active region, and has a second length in the second direction. A length in the second direction of a first overlap region between the first active region and the first source/drain contact is less than the first width of the first active region.

According to another aspect of an embodiment, an integrated circuit includes: a first active region extending in a first direction on a substrate; a second active region extending in the first direction on the substrate, wherein the second active region is spaced apart from the first active region in a second direction, and the second direction intersects the first direction; a first source/drain contact extending in the second direction above the first active region, wherein the first source/drain contact is connected to a power line for supplying power, and has a first length in the second direction; a second source/drain contact extending in the second direction above the first active region, wherein the second source/drain contact is connected to a signal line for transmitting a signal, and has a second length in the second direction; a third source/drain contact extending in the second direction above the second active region, wherein the third source/drain contact has a third length in the second direction; and a via disposed only on the second source/drain contact among the second and third source/drain contacts, wherein the via connects the second source/drain contact to the signal line. A length in the second direction of a first overlap region between the first source/drain contact and the first active region is greater than a length in the second direction of a second overlap region between the second source/drain contact and the first active region.

### BRIEF DESCRIPTION OF DRAWINGS

The above and other aspects and features will be more apparent from the following description of embodiments, taken in conjunction with the accompanying drawings, in which:

FIG. 1 shows a layout of an integrated circuit according to an embodiment;

FIG. 2 shows a circuit diagram of the integrated circuit of FIG. 1, according to an embodiment;

FIG. 3 shows a portion of the integrated circuit of FIG. 1, according to an embodiment;

FIG. 4A is an example of a cross-sectional view of the integrated circuit taken along line Y1-Y1′ in FIG. 1, FIG. 4B is an example of a cross-sectional view of the integrated circuit taken along line Y2-Y2′ in FIG. 1, FIG. 4C is an example of a cross-sectional view of the integrated circuit taken along line Y3-Y3′ in FIG. 1, FIG. 4D is an example of a cross-sectional view of the integrated circuit taken along line Y4-Y4′ in FIG. 1, and FIG. 4E is an example of a cross-sectional view of the integrated circuit taken along line Y5-Y5′ in FIG. 1;

FIG. 5 shows a layout of an integrated circuit according to an embodiment;

FIG. 6 shows a portion of the integrated circuit of FIG. 5, according to an embodiment;

FIG. 7 shows a layout of an integrated circuit according to an embodiment;

FIG. 8 shows a layout of an integrated circuit according to an embodiment;

FIG. 9 shows a layout of an integrated circuit according to an embodiment;

FIG. 10 shows a layout of an integrated circuit according to an embodiment;

FIG. 11 shows a portion of the integrated circuit of FIG. 10, according to an embodiment;

FIG. 12A is an example of a cross-sectional view of the integrated circuit taken along line Y6-Y6′ in FIG. 10, FIG. 12B is an example of a cross-sectional view of the integrated circuit taken along line Y7-Y7′ in FIG. 10, FIG. 12C is an example of a cross-sectional view of the integrated circuit taken along line Y8-Y8′ in FIG. 10, and FIG. 12D is an example of a cross-sectional view of the integrated circuit taken along line Y9-Y9′ in FIG. 10;

FIG. 13 shows a layout of an integrated circuit according to an embodiment;

FIG. 14 shows a portion of the integrated circuit of FIG. 13, according to an embodiment;

FIG. 15 shows a layout of a single height cell according to an embodiment;

FIG. 16 shows a layout of a first double height cell according to an embodiment;

FIG. 17 shows a layout of a second double height cell according to an embodiment;

FIGS. 18A, 18B, 18C and 18D each show a device according to some embodiments; and

FIG. 19 is a flowchart showing a method of manufacturing an integrated circuit, according to an embodiment.

### DETAILED DESCRIPTION

Hereinafter, embodiments are described in detail with reference to the accompanying drawings. The same reference numerals are given to the same elements in the drawings, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

As used herein, an X-axis direction may be referred to as a first direction, a Y-axis direction may be referred to as a second direction, and a Z-axis direction may be referred to as a vertical direction. A plane defined by the X-axis and the Y-axis may be referred to as a horizontal plane. Also, a component disposed in the +Z-axis direction relative to other components may be referred to as being above other components, and a component disposed in the −Z-axis direction relative to other components may be referred to as being below other components.

An integrated circuit may be designed by arranging a plurality of standard cells. A standard cell is a unit of layout of an integrated circuit, and may be referred to as a “cell” according to embodiments. The standard cell may be designed to include a plurality of transistors so as to perform a predefined function. Standard cells are pre-designed, verified, and then registered in a standard cell library. An integrated circuit may be designed by performing logic design, placement, and routing on standard cells which are combined together by using computer-aided design (CAD).

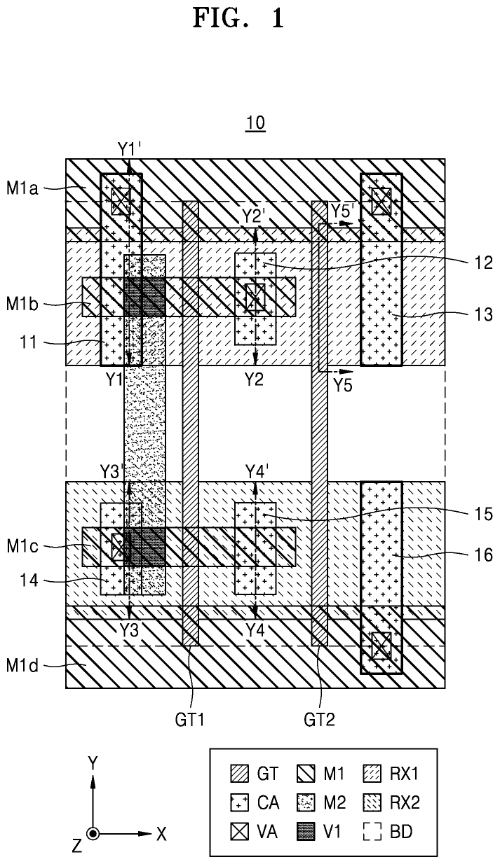

FIG. 1 shows a layout of an integrated circuit 10 according to an embodiment.

Referring to FIG. 1, the integrated circuit 10 may include first and second active regions RX1 and RX2, a plurality of source/drain contacts CA, a plurality of gate lines GT, a plurality of first vias VA, a plurality of second vias V1, a first wiring layer M1, and a second wiring layer M2. According to an embodiment, the integrated circuit 10 may be referred to as an “integrated circuit device” or a “semiconductor device.” For example, the first and second active regions RX1 and RX2, the plurality of source/drain contacts CA, and the plurality of gate lines GT may constitute a standard cell, and the standard cell may be defined by a cell boundary BD.

The first and second active regions RX1 and RX2 may each extend in a first direction X and be spaced apart from each other in a second direction Y intersecting the first direction X. In some embodiments, the first and second active regions RX1 and RX2 may include semiconductors (i.e., semiconductor materials), such as Si and Ge, or compound semiconductors, such as SiGe, SiC, GaAs, InAs, and InP, and may also include conductive regions, for example, a well doped with impurities or a structure doped with impurities. For example, the first active region RX1 may include a region doped with a first conductivity-type impurities, and the second active region RX2 may include a region doped with a second conductivity-type impurities. The first active region RX1 may have a first width W1 in the second direction Y and the second active region RX2 may have a second width W2 in the second direction Y. For example, the first width W1 may be equal to the second width W2, but embodiments are not limited thereto.

The plurality of source/drain contacts CA may include first to sixth source/drain contacts 11 to 16, each of which extends in the second direction Y. The first to sixth source/drain contacts 11 to 16 may have different lengths in the second direction Y. According to embodiments, the lengths of the first to sixth source/drain contacts 11 to 16 may be formed differently from each other, according to the characteristics of each of the first to sixth source/drain contacts 11 to 16 or according to a net corresponding to each of the first to sixth source/drain contacts 11 to 16. Accordingly, in the second direction Y, at least one of the lengths of the first active region RX1 respectively overlapping the first to third source/drain contacts 11 to 13 and/or the lengths of the second active region RX2 respectively overlapping the fourth to sixth source/drain contacts 14 to 16 may be different from the others.

In an embodiment, the first, third, and sixth source/drain contacts 11, 13, and 16 may correspond to a power net for supplying power supply voltage, and the second, fourth, and fifth source/drain contacts 12, 14, and 15 may correspond to a signal net for transmitting signals. According to an embodiment, the source/drain contacts corresponding to the power net may be referred to as “power contacts,” and the source/drain contacts corresponding to the signal net may be referred to as “signal contacts.” In FIG. 1, in order to distinguish the power contacts from the signal contacts, the outlines of the first, third, and sixth source/drain contacts 11, 13, and 16 are illustrated as thicker lines, and the outlines of the second, fourth, and fifth source/drain contacts 12, 14, and 15 are illustrated as thinner lines.

For example, the first to third source/drain contacts 11 to 13 may each extend in the second direction Y above the first active region RX1, and the first to third source/drain contacts 11 to 13 may have different lengths in the second direction Y. Accordingly, the overlap regions in which the first to third source/drain contacts 11 to 13 overlap the first active region RX1 or the regions in which the first to third source/drain contacts 11 to 13 are in contact with the first active region RX1 may have different lengths in the second direction Y.

For example, the fourth to sixth source/drain contacts 14 to 16 may each extend in the second direction Y above the second active region RX2, and the fourth to sixth source/drain contacts 14 to 16 may have different lengths in the second direction Y. Accordingly, the overlap regions in which the fourth to sixth source/drain contacts 14 to 16 overlap the second active region RX2 or the regions in which the fourth to sixth source/drain contacts 14 to 16 are in contact with the second active region RX2 may have different lengths in the second direction Y.

The plurality of gate lines GT may include first and second gate lines GT1 and GT2. For example, the first gate line GT1 may extend in the second direction Y above the first and second active regions RX1 and RX2, and may be located between the first and second source/drain contacts 11 and 12 and between the fourth and fifth source/drain contacts 14 and 15. For example, the second gate line GT2 may extend in the second direction Y above the first and second active regions RX1 and RX2, and may be located between the second and third source/drain contacts 12 and 13 and between the fifth and sixth source/drain contacts 15 and 16.

The first wiring layer M1 may include first to fourth wiring patterns M1a to M1d each extending in the first direction X above the plurality of source/drain contacts CA and the plurality of gate lines GT. The second wiring layer M2 may extend in the second direction Y above the first wiring layer M1. According to an embodiment, the first wiring layer M1 may be referred to as a first front-side wiring layer, and the second wiring layer M2 may be referred to as a second front-side wiring layer.

In an embodiment, the first and fourth wiring patterns M1a and M1d may correspond to “power lines.” For example, the first wiring pattern M1a may overlap an upper boundary of a standard cell and receive a first supply voltage, for example, a power supply voltage. The first wiring pattern M1a may be electrically connected to the first and third source/drain contacts 11 and 13 via the first vias VA and may supply the power supply voltage to the first and third source/drain contacts 11 and 13. For example, the fourth wiring pattern M1d may overlap a lower boundary of the standard cell and receive a second supply voltage, for example, a ground voltage. The fourth wiring pattern M1d may be electrically connected to the sixth source/drain contact 16 via the first vias VA and may supply the ground voltage to the sixth source/drain contact 16.

The power supply voltage may represent the voltage required for the operation of a semiconductor device (e.g., a transistor) and may be an essential factor in ensuring the normal operation and reliability of the device. However, when current flows, a voltage drop, i.e., an IR drop, occurs in the power supply voltage due to the current flowing through resistive components on a power supply routing path. This IR drop may cause the voltage applied to a specific point in a circuit to fall below the design reference, resulting in malfunction or performance degradation of the device. In addition, the operating margin of devices is gradually decreasing due to microfabrication, and wire resistance is increasing due to a reduction in the cross-sectional areas of wires. As a result, the effect of IR drop becomes even more critical. Therefore, when designing the integrated circuit 10, it is essential to consider the IR drop in advance and prepare corresponding measures.

Therefore, according to embodiments, each of the first, third, and sixth source/drain contacts 11, 13, and 16 connected to the power lines may be made relatively long in length in order to reduce the IR drop on a power supply path. Accordingly, the region in which each of the first and third source/drain contacts 11 and 13 overlaps the first active region RX1 and the region in which the sixth source/drain contact 16 overlaps the second active region RX2 may be made relatively long in length. Accordingly, the amount of current that may be applied via each of the first, third, and sixth source/drain contacts 11, 13, and 16 may be increased by lowering the resistance of each of the first, third, and sixth source/drain contacts 11, 13, and 16 connected to the power net. Therefore, the power supply efficiency in the integrated circuit 10 may be improved, the effect of IR drop may be reduced. Consequently, the overall performance and operating stability of the integrated circuit 10 may be improved.

In an embodiment, the second and third wiring patterns M1b and M1c may correspond to “signal lines.” For example, the second wiring pattern M1b may be disposed above the first active region RX1, and the third wiring pattern M1c may be disposed above the second active region RX2. For example, an output signal may be transmitted via the second and third wiring patterns M1b and M1c. For example, the second source/drain contact 12 may be electrically connected to the second wiring pattern M1b via a first via VA and may transmit an output signal to the second wiring pattern M1b. For example, the fourth source/drain contact 14 may be electrically connected to the third wiring pattern M1c via a first via VA and may transmit an output signal to the third wiring pattern M1c.

In the signal transmission path, capacitance may be an important factor affecting performance. Specifically, during a switching operation in which a signal in the integrated circuit 10 switches from a high potential state to a low potential state (or vice versa), a rise time and a fall time of the signal relate to the load capacitance of an output node. Generally, because a charge/discharge time increases as the load capacitance increases, the transition time of the output signal becomes longer, which may lead to a decrease in the speed of the total circuit. On the other hand, when the load capacitance decreases, the voltage changes rapidly during switching, which increases a switching speed of a signal and enables a high-speed operation.

Therefore, when lowering the capacitance on the signal transmission path as much as possible, it is advantageous in terms of improving the response speed of a circuit, transmitting data at high speed, and reducing power consumption, and it may ultimately contribute to improving the performance of the integrated circuit 10. For this reason, according to embodiments, each of the second and fourth source/drain contacts 12 and 14 connected to the signal lines may be made relatively short in length in order to reduce the capacitance of the signal lines. Accordingly, the region in which the second source/drain contact 12 overlaps the first active region RX1 and the region in which the fourth source/drain contact 14 overlaps the second active region RX2 may be made relatively short in length. Therefore, the switching speed of the signals transmitted via each of the second and fourth source/drain contacts 12 and 14 may be improved by reducing the capacitance of each of the second and fourth source/drain contacts 12 and 14 connected to the signal net. Therefore, the signal transmission efficiency in the integrated circuit 10 may be improved, and as a result, the overall performance of the integrated circuit 10 may be improved.

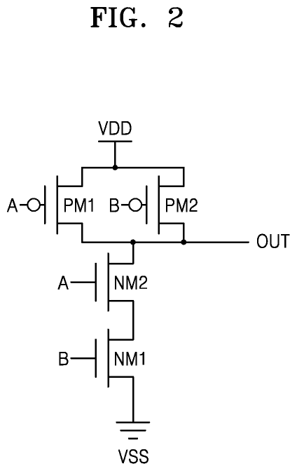

FIG. 2 shows a circuit diagram of the integrated circuit 10 of FIG. 1, according to an embodiment.

Referring to FIG. 2, the integrated circuit 10 may include first and second P-type transistors PM1 and PM2 and first and second N-type transistors NM1 and NM2. The first and second P-type transistors PM1 and PM2 may be connected to each other in parallel, and the first and second N-type transistors NM1 and NM2 may be connected to each other in series. Accordingly, the integrated circuit 10 may include an NAND gate cell.

The first P-type transistor PM1 may include a source for receiving a power supply voltage VDD, a gate for receiving a first input signal A, and a drain connected to an output node OUT. The second P-type transistor PM2 may include a source for receiving the power supply voltage VDD, a gate for receiving a second input signal B, and a drain connected to the output node OUT. The first N-type transistor NM1 may include a source for receiving a ground voltage VSS and a gate for receiving the second input signal B. The second N-type transistor NM2 may include a gate for receiving the first input signal A and a drain connected to the output node OUT.

Referring to FIGS. 1 and 2 together, the first gate line GT1 and the first and second source/drain contacts 11 and 12 may constitute the first P-type transistor PM1, and the second gate line GT2 and the second and third source/drain contacts 12 and 13 may constitute the second P-type transistor PM2. Also, the first gate line GT1 and the fourth and fifth source/drain contacts 14 and 15 may constitute the second N-type transistor NM2, and the second gate line GT2 and the fifth and sixth source/drain contacts 15 and 16 may constitute the first N-type transistor NM1.

The first and third source/drain contacts 11 and 13 may correspond to the sources of the first and second P-type transistors PM1 and PM2 that receive the power supply voltage VDD, thereby forming a first power net. The sixth source/drain contact 16 may correspond to the source of the first N-type transistor NM1 that receives the ground voltage VSS, thereby forming a second power net. As described above, the first, third, and sixth source/drain contacts 11, 13, and 16 connected to the first and second power nets may be relatively long. Accordingly, the power supply efficiency may be improved by reducing the resistance of the first, third, and sixth source/drain contacts 11, 13, and 16.

The second and fourth source/drain contacts 12 and 14 may correspond to the output node OUT, thereby forming a signal net through which an output signal is transmitted. The fifth source/drain contact 15 may correspond to a connection node between the first and second N-type transistors NM1 and NM2. Hereinafter, based on the second source/drain contact 12, the source/drain contact connected to the signal net is described below. The following description may also apply to the fourth and fifth source/drain contacts 14 and 15.

For example, the second source/drain contact 12 may generate parasitic capacitances by coupling with the first and second gate lines GT1 and GT2 adjacent thereto. These parasitic capacitances may adversely affect the transmission characteristics of the output signal transmitted via the second source/drain contact 12, the transmission characteristics of the first input signal A input via the first gate line GT1, and/or the transmission characteristics of the second input signal B input via the second gate line GT2. Specifically, the parasitic capacitances may form an unnecessary charge/discharge path between the first gate line GT1 and the second source/drain contact 12 and between the second gate line GT2 and the second source/drain contact 12, thereby causing additional consumption of current during switching of the output signal and/or the first and second input signals A and B. That is, when the output signal and/or the first and second input signals A and B switch logic states, additional current is required to charge or discharge the parasitic capacitances, which causes an increase in the operating power consumption of the total circuit.

Also, the parasitic capacitances may directly affect the transition speed of the output signal and/or the first and second input signals A and B, thereby delaying the rise time or the fall time of a signal. As a result, the response characteristics of the signal may deteriorate, thereby reducing the timing margin, increasing interference between signals, or increasing the possibility of malfunction during a high-speed operation.

According to embodiments, the parasitic capacitances between the first and second gate lines GT1 and GT2 may be minimized by making the length of the second source/drain contact 12 relatively small. As a result, the response characteristics of the output signal and/or the first and second input signals A and B may be improved, the unnecessary current consumption may be reduced, and the overall power efficiency and signal integrity of the integrated circuit may be improved.

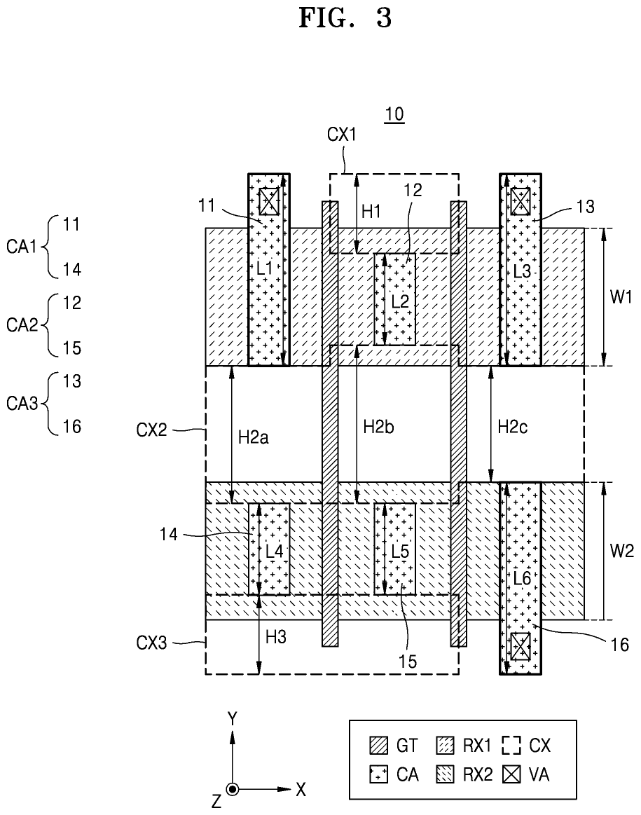

FIG. 3 shows a portion of the integrated circuit 10 of FIG. 1, according to an embodiment.

Referring to FIGS. 1 to 3, the integrated circuit 10 may further include cutting regions CX. The cutting regions CX may include first to third cutting regions CX1, CX2, and CX3. A first contact CA1 may be divided into the first and fourth source/drain contacts 11 and 14 by the second cutting region CX2, a second contact CA2 may be divided into the second and fifth source/drain contacts 12 and 15 by the second cutting region CX2, and a third contact CA3 may be divided into the third and sixth source/drain contacts 13 and 16 by the second cutting region CX2.

The first cutting region CX1 may have a rectangular shape with a first height H1 in the second direction Y. The third cutting region CX3 may have a rectangular shape with a third height H3 in the second direction Y. The second cutting region CX2 may have a polygonal shape with different lengths in the second direction Y. For example, the second cutting region CX2 may have a height H2a between the first power net and the signal net, i.e., between the first and fourth source/drain contacts 11 and 14. For example, the second cutting region CX2 may have a height H2b between portions of the signal net, i.e., between the second and fifth source/drain contacts 12 and 15. For example, the second cutting region CX2 may have a height H2c between the signal net and the second power net, i.e., between the third and sixth source/drain contacts 13 and 16. For example, the first to third heights H2a, H2b, and H2c may differ from each other. Accordingly, the first to sixth source/drain contacts 11 to 16 may have different lengths in the second direction Y.

The first source/drain contact 11 may have a first length L1 in the second direction Y, and a first overlap region between the first source/drain contact 11 and the first active region RX1 may have a length corresponding to the first width W1 in the second direction Y. The first length L1 of the first source/drain contact 11 corresponding to the first power net may be relatively long, and the length of the first overlap region in which the first source/drain contact 11 overlaps the first active region RX1 may be relatively long. Accordingly, the resistance of the first power net may be reduced, thereby improving the supply efficiency of the first supply voltage, for example, the power supply voltage VDD.

The second source/drain contact 12 may be configured such that the upper edge thereof is located inside the first active region RX1 by the first cutting region CX1 and the lower edge thereof is located inside the first active region RX1 by the second cutting region CX2. Accordingly, the second source/drain contact 12 may have a second length L2 less than the first length L1 in the second direction Y, and the length of a second overlap region between the second source/drain contact 12 and the first active region RX1 may correspond to the second length L2. In this case, the capacitance of the second source/drain contact 12 may be relatively small. For example, the capacitance between the second source/drain contact 12 and the first gate line GT1 may be less than the capacitance between the first source/drain contact 11 and the first gate line GT1. Accordingly, the capacitance of the signal net may be reduced, thereby improving the transmission efficiency of the output signal and/or the input signal.

The third source/drain contact 13 may have a third length L3 in the second direction Y, and a third overlap region between the third source/drain contact 13 and the first active region RX1 may have a length corresponding to the first width W1 in the second direction Y. For example, the first length L1 may be equal to the third length L3, but embodiments are not limited thereto. The third length L3 of the third source/drain contact 13 corresponding to the first power net may be relatively long, and the length of the third overlap region in which the third source/drain contact 13 overlaps the first active region RX1 may be relatively long. Accordingly, the resistance of the first power net may be reduced, thereby improving the supply efficiency of the first supply voltage, for example, the power supply voltage VDD.

The fourth source/drain contact 14 may be configured such that the upper edge thereof is located inside the second active region RX2 by the second cutting region CX2 and the lower edge thereof is located inside the second active region RX2 by the third cutting region CX3. Accordingly, the fourth source/drain contact 14 may have a fourth length L4 in the second direction Y, and the length of a fourth overlap region between the fourth source/drain contact 14 and the second active region RX2 may correspond to the fourth length L4. For example, the fourth length L4 may be equal to the second length L2, but embodiments are not limited thereto. In this case, the capacitance of the fourth source/drain contact 14 may be relatively small, thereby reducing the capacitance of the signal net. Therefore, the transmission efficiency of the output signal and/or the input signal may be improved.

The fifth source/drain contact 15 may be configured such that the upper edge thereof is located inside the second active region RX2 by the second cutting region CX2 and the lower edge thereof is located inside the second active region RX2 by the third cutting region CX3. Accordingly, the fifth source/drain contact 15 may have a fifth length L5 in the second direction Y, and the length of a fifth overlap region between the fifth source/drain contact 15 and the second active region RX2 may correspond to the fifth length L5. For example, the fifth length L5 may be equal to the fourth length L4, but embodiments are not limited thereto. Accordingly, as the length of the fifth source/drain contact 15 corresponding to the connection node is made relatively short, the capacitance of the fifth source/drain contact 15 may be reduced, thereby improving an RC delay.

The sixth source/drain contact 16 may have a sixth length L6 in the second direction Y, and a sixth overlap region between the sixth source/drain contact 16 and the second active region RX2 may have a length corresponding to the second width W2 in the second direction Y. For example, the sixth length L6 may be equal to the first length L1 and/or the third length L3, but embodiments are not limited thereto. The length of the sixth source/drain contact 16 corresponding to the second power net may be relatively long, and thus, the length of the sixth overlap region in which the sixth source/drain contact 16 overlaps the second active region RX2 may be relatively long. Accordingly, the resistance of the second power net may be reduced, thereby improving the supply efficiency of the second supply voltage, for example, the ground voltage VSS.

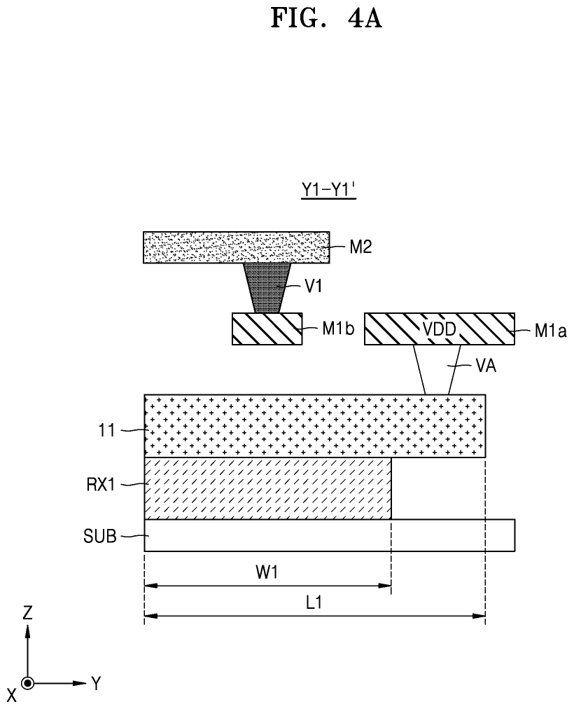

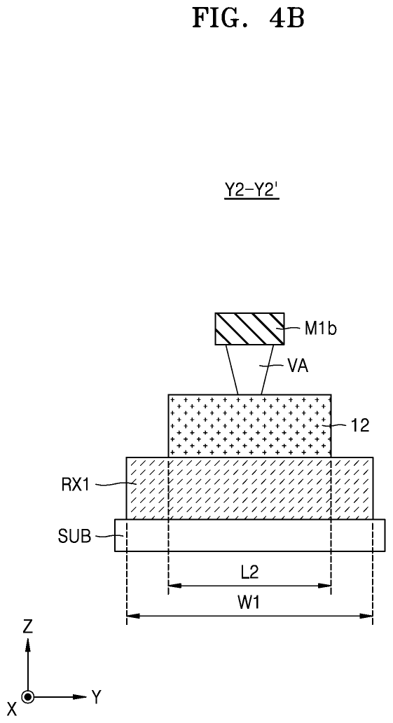

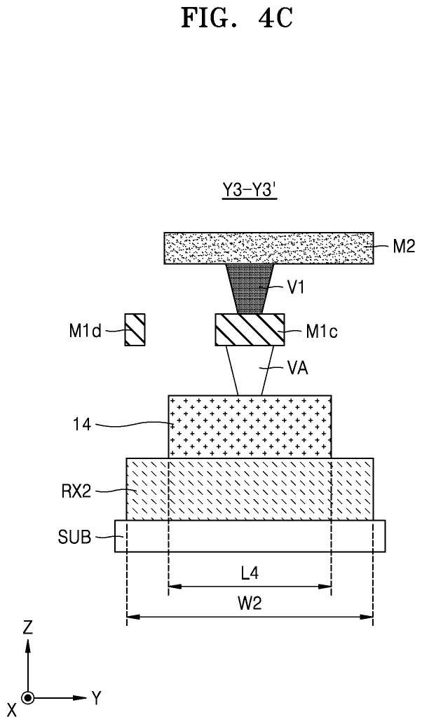

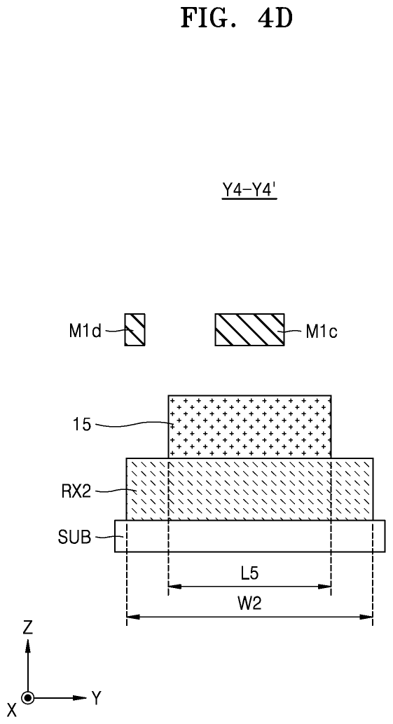

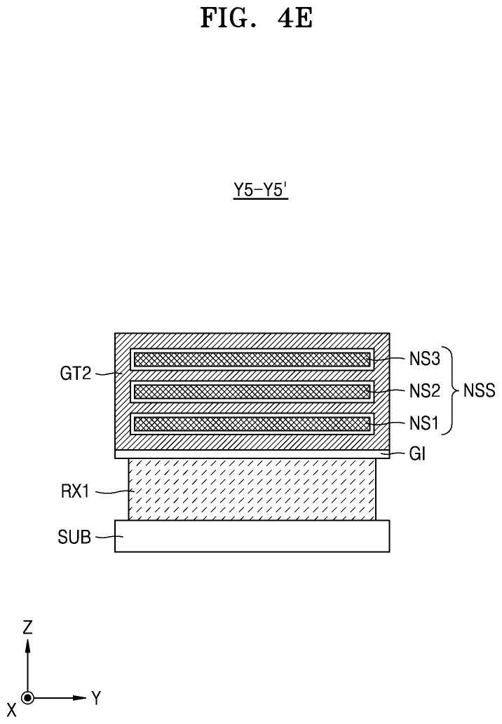

FIG. 4A is an example of a cross-sectional view of the integrated circuit 10 taken along line Y1-Y1′ in FIG. 1, FIG. 4B is an example of a cross-sectional view of the integrated circuit 10 taken along line Y2-Y2′ in FIG. 1, FIG. 4C is an example of a cross-sectional view of the integrated circuit 10 taken along line Y3-Y3′ in FIG. 1, FIG. 4D is an example of a cross-sectional view of the integrated circuit 10 taken along line Y4-Y4′ in FIG. 1, and FIG. 4E is an example of a cross-sectional view of the integrated circuit 10 taken along line Y5-Y5′ in FIG. 1.

FIGS. 4A to 4E illustrate an example in which nanosheets are formed in an active region. For example, a multi-bridge channel field effect transistor (MBCFET) may be formed in which a plurality of nanosheets are stacked in the active region and a gate line surrounds the plurality of nanosheets. However, the integrated circuit according to embodiments is not limited to those shown in FIGS. 4A to 4E. For example, a gate-all-around field effect transistor (GAAFET) may be formed in which nanowires formed in an active region are surrounded by a gate line.

Referring to FIGS. 4A to 4E together, the first and second active regions RX1 and RX2 may be defined by a device isolation layer (e.g., a shallow trench isolation) on a substrate SUB. For example, the substrate SUB may include a silicon-on-insulator (SOI) substrate or a germanium-on-insulator (GOI) substrate. For example, the substrate SUB may include a P-type substrate doped with P-type impurities. The first active region RX1 may have the first width W1, the second active region RX2 may have the second width W2, and the first width W1 may be equal to the second width W2. For example, the first active region RX1 may include an N-well doped with N-type impurities, and in this case, P-type transistors (e.g., PM1, PM2) may be formed in the N-well. For example, the second active region RX2 may include a P-well doped with P-type impurities, and in this case, N-type transistors (e.g., NM1, NM2 in FIG. 2) may be formed in the P-well. In some embodiments, the first and second active regions RX1 and RX2 may each be understood to include source/drain regions and/or channel regions.

A gate insulating layer GI may be disposed on the substrate SUB. Active patterns, such as nanosheets, may be formed above the gate insulating layer GI. In this case, the nanosheets may function as a channel of a transistor. A nanosheet stack NSS may include nanosheets NS1 to NS3 that are spaced apart from each other in the vertical direction Z. The second gate line GT2 may cover the nanosheet stack NSS and surround each of the nanosheets NS1 to NS3. The nanosheets NS1 to NS3 may have a gate-all-around (GAA) structure that is surrounded by the second gate line GT2. The gate insulating layer GI may be located between the nanosheets NS1 to NS3 and the second gate line GT2. The second gate line GT2 may be defined as a conductive segment that includes conductive materials, such as polysilicon and one or more metals.

The first source/drain contact 11 may have the first length L1, and the length of the region in which the first source/drain contact 11 is in contact with the first active region RX1, i.e., the first overlap region, may correspond to the first width W1. The first source/drain contact 11 may be electrically connected to the first wiring pattern M1a via the first via VA and may receive the power supply voltage VDD from the first wiring pattern M1a. In this case, the length of the region in which the first source/drain contact 11 is in contact with the first active region RX1 may correspond to the first width W1, and thus, the IR drop may be reduced.

The second source/drain contact 12 may have the second length L2, and the length of the region in which the second source/drain contact 12 is in contact with the first active region RX1, i.e., the second overlap region, may correspond to the second length L2. The second source/drain contact 12 may be electrically connected to the second wiring pattern M1b via the first via VA and may transmit the output signal via the second wiring pattern M1b. In this case, the length of the region in which the second source/drain contact 12 is in contact with the first active region RX1 may be relatively short, and thus, the capacitance may be reduced.

The fourth source/drain contact 14 may have the fourth length L4, and the length of the region in which the fourth source/drain contact 14 is in contact with the second active region RX2, i.e., the fourth overlap region, may correspond to the fourth length L4. The fourth source/drain contact 14 may be electrically connected to the third wiring pattern M1c via the first via VA and may transmit the output signal via the third wiring pattern M1c. In this case, the length of the region in which the fourth source/drain contact 14 is in contact with the second active region RX2 may be relatively short, and thus, the capacitance may be reduced.

The fifth source/drain contact 15 may have the fifth length L5, and the length of the region in which the fifth source/drain contact 15 is in contact with the second active region RX2, i.e., the fifth overlap region, may correspond to the fifth length L5. The first via VA may not be disposed on the fifth source/drain contact 15, and the fifth source/drain contact 15 may correspond to the connection node between the first and second N-type transistors NM1 and NM2. In this case, because the length of the region in which the fifth source/drain contact 15 is in contact with the second active region RX2 is relatively short, the capacitance may be reduced. Therefore, the RC delay of the signal transmitted via the connection node may be improved.

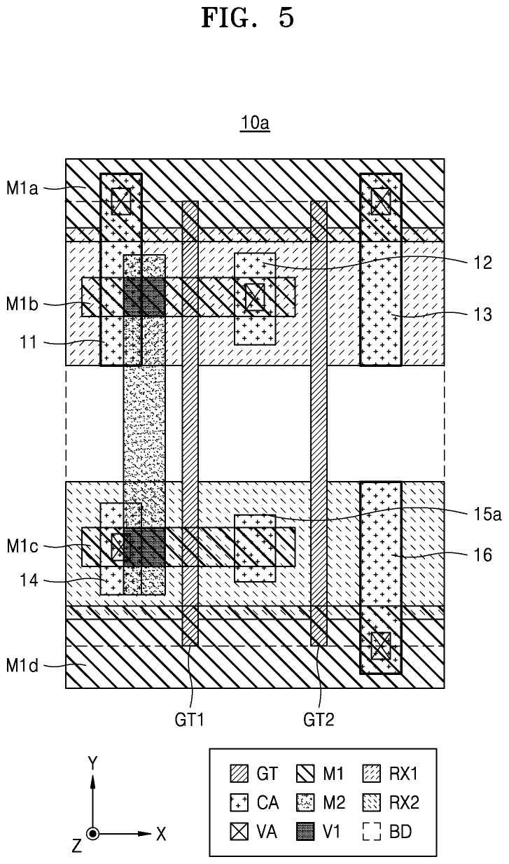

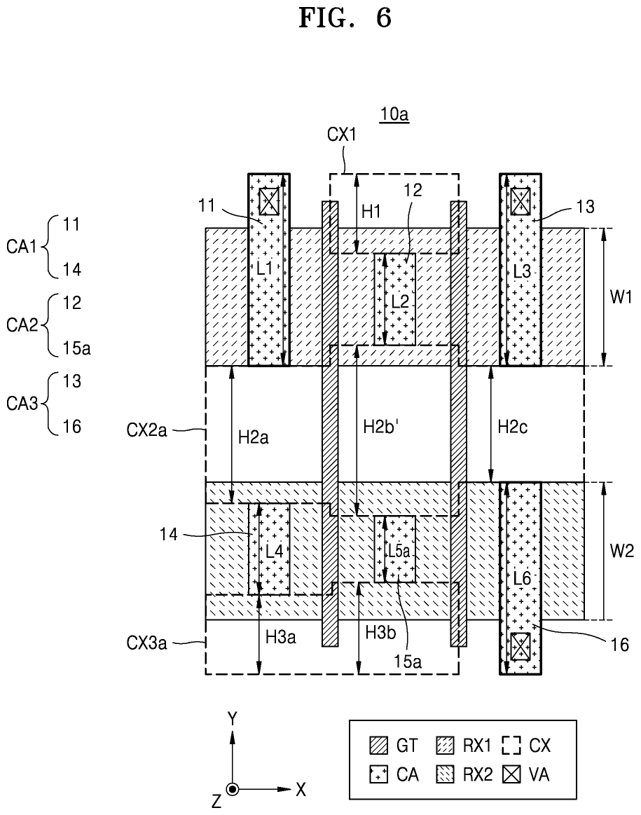

FIG. 5 shows a layout of an integrated circuit 10a according to an embodiment. FIG. 6 shows a portion of the integrated circuit 10a of FIG. 5, according to an embodiment.

Referring to FIGS. 5 and 6 together, the integrated circuit 10a corresponds to a modified example of the integrated circuit 10 in FIG. 1, and the descriptions given above with reference to FIGS. 1 to 4E may also apply to the integrated circuit 10a. The second contact CA2 may be divided into second and fifth source/drain contacts 12 and 15a by a second cutting region CX2a. According to an embodiment, the second and third cutting regions CX2a and CX3a may each be formed as a polygon having different lengths in the second direction Y.

The second cutting region CX2a may have a polygonal shape with different lengths in the second direction Y. For example, the second cutting region CX2a may have a height H2b′ between portions of the signal net, i.e., between the second and fifth source/drain contacts 12 and 15a. For example, the height H2b′ may be greater than height H2b in FIG. 3. The third cutting region CX3a may have a height H3a in the second direction Y in a region adjacent to the fourth source/drain contact 14 and a height H3b in the second direction Y in a region adjacent to the fifth source/drain contact 15a. For example, the height H3b may be greater than the height H3a, and thus, the fifth source/drain contact 15a may have a shorter length than the fifth source/drain contact 15 in FIG. 3.

Particularly, the fifth source/drain contact 15a may be configured such that the upper edge thereof is located inside the second active region RX2 by the second cutting region CX2a and the lower edge thereof is located inside the second active region RX2 by the third cutting region CX3a. Accordingly, the fifth source/drain contact 15a may have a fifth length L5a in the second direction Y, and the length of the fifth overlap region in which the fifth source/drain contact 15a overlaps the second active region RX2 may correspond to the fifth length L5a. In this case, the fifth length L5a may be less than the fifth length L5 in FIG. 3, and thus, the capacitance of the fifth source/drain contact 15a may be further reduced. Therefore, the RC delay of the signal transmitted via the connection node may be further improved.

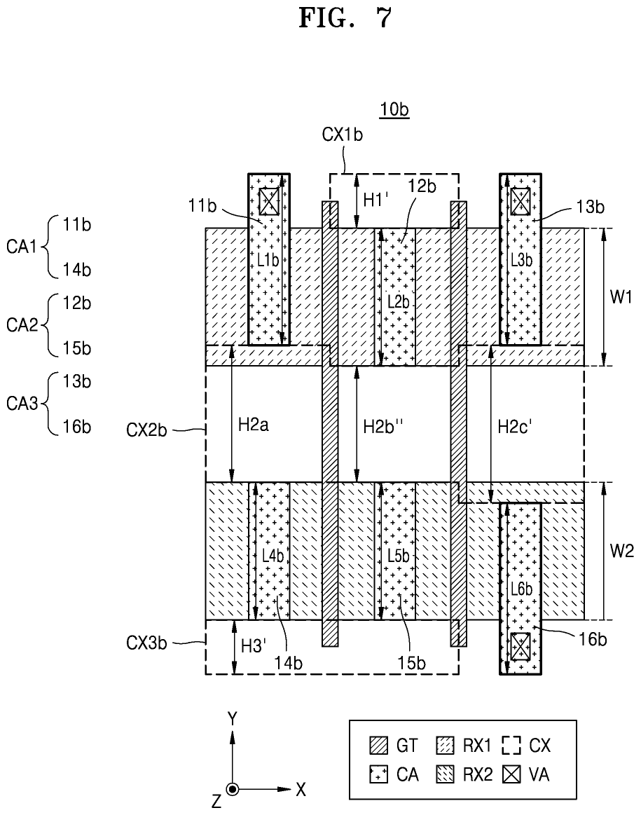

FIG. 7 shows a layout of an integrated circuit 10b according to an embodiment.

Referring to FIG. 7, the integrated circuit 10b corresponds to a modified example of the integrated circuit 10 in FIG. 1 or the integrated circuit 10a in FIG. 5, and the descriptions given above with reference to FIGS. 1 to 6 may also apply to the integrated circuit 10b. The first contact CA1 may be divided into first and fourth source/drain contacts 11b and 14b by a second cutting region CX2b. The second contact CA2 may be divided into second and fifth source/drain contacts 12b and 15b by the second cutting region CX2b. The third contact CA3 may be divided into third and sixth source/drain contacts 13b and 16b by the second cutting region CX2b.

A first cutting region CX1b may be formed as a rectangle having a first height H1′ in the second direction Y. For example, the first height H1′ may be less than the first height H1 in FIG. 3, and a second length L2b of the second source/drain contact 12b may be greater than the second length L2 of the second source/drain contact 12 in FIG. 3. Also, a third cutting region CX3b may be formed as a rectangle having a third height H3′ in the second direction Y. For example, the third height H3′ may be smaller than the third height H3 in FIG. 3. Accordingly, a fifth length L5b of the fifth source/drain contact 15b may be greater than the fifth length L5 of the fifth source/drain contact 15 in FIG. 3, and a fourth length L4b of the fourth source/drain contact 14b may be greater than the fourth length L4 of the fourth source/drain contact 14 in FIG. 3.

The second cutting region CX2b may have a polygonal shape with different lengths in the second direction Y. For example, the second cutting region CX2b may have the height H2a between the first power net and the signal net, i.e., between the first and fourth source/drain contacts 11b and 14b. In this case, the second cutting region CX2b between the first power net and the signal net may be shifted upward compared to FIG. 3. Accordingly, a first length L1b of the first source/drain contact 11b may be less than the first length L1 of the first source/drain contact 11 in FIG. 3, and the fourth length L4b of the fourth source/drain contact 14b may be greater than the fourth length L4 of the fourth source/drain contact 14 in FIG. 3.

For example, the second cutting region CX2b may have a height H2b″ between portions of the signal net, i.e., between the second and fifth source/drain contacts 12b and 15b. For example, the height H2b″ may be less than the height H2b in FIG. 3. Accordingly, the second length L2b of the second source/drain contact 12b may be greater than the second length L2 of the second source/drain contact 12 in FIG. 3, and the fifth length L5b of the fifth source/drain contact 15b may be greater than the fifth length L5 of the fifth source/drain contact 15 in FIG. 3.

For example, the second cutting region CX2b may have a height H2c′ between the first power net and the second power net, i.e., between the third and sixth source/drain contacts 13b and 16b. For example, the height H2c′ may be greater than the height H2c in FIG. 3. Accordingly, a third length L3b of the third source/drain contact 13b may be less than the third length L3 of the third source/drain contact 13 in FIG. 3, and a sixth length L6b of the sixth source/drain contact 16b may be less than the sixth length L6 of the sixth source/drain contact 16 in FIG. 3.

Accordingly, as the length of each of the first, third, and sixth source/drain contacts 11b, 13b, and 16b corresponding to the power nets is reduced, the length of the region in which each of the first, third, and sixth source/drain contacts 11b, 13b, and 16b is in contact with the active region corresponding thereto may be reduced. Also, as the length of each of the second and fourth source/drain contacts 12b and 14b and the fifth source/drain contact 15b corresponding to the signal net is increased, the length of the region in which each of the second, fourth, and fifth source/drain contacts 12b, 14b, and 15b is in contact with the active region corresponding thereto may be increased.

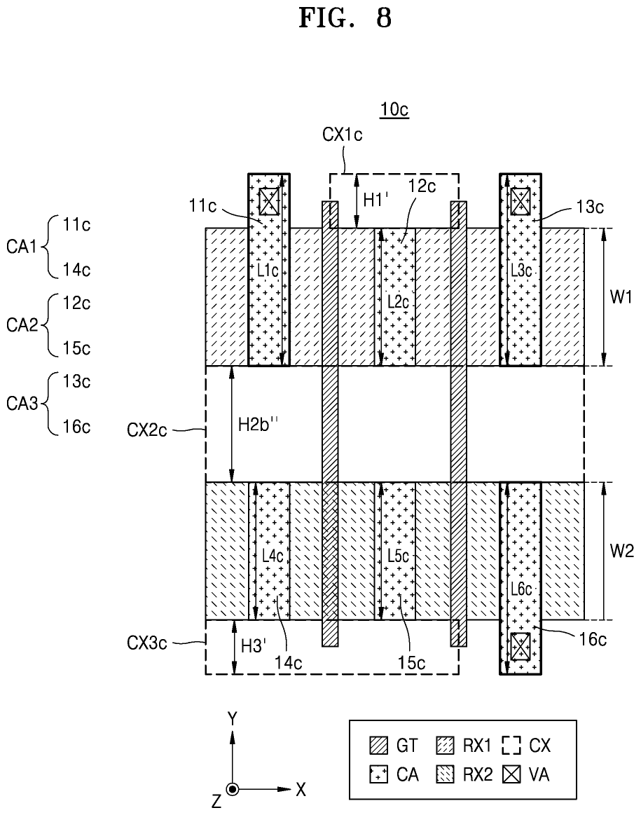

FIG. 8 shows a layout of an integrated circuit 10c according to an embodiment.

Referring to FIG. 8, the integrated circuit 10c corresponds to a modified example of the integrated circuit 10b in FIG. 7, and the descriptions given above with reference to FIG. 7 may also apply to the integrated circuit 10c. The first contact CA1 may be divided into first and fourth source/drain contacts 11c and 14c by a second cutting region CX2c. The second contact CA2 may be divided into second and fifth source/drain contacts 12c and 15c by the second cutting region CX2c. The third contact CA3 may be divided into third and sixth source/drain contacts 13c and 16c by the second cutting region CX2c. According to an embodiment, each of the first to third cutting regions CX1c, CX2c, and CX3c may be formed as a rectangle.

The second cutting region CX2c may have a rectangular shape with the second height H2b″ in the second direction Y. Accordingly, a first length L1c of the first source/drain contact 11c may be greater than the first length L1b of the first source/drain contact 11b in FIG. 7. Also, a third length L3c of the third source/drain contact 13c may be greater than the third length L3b of the third source/drain contact 13b in FIG. 7. Furthermore, a sixth length L6c of the sixth source/drain contact 16c may also be greater than the sixth length L6b of the sixth source/drain contact 16b in FIG. 7.

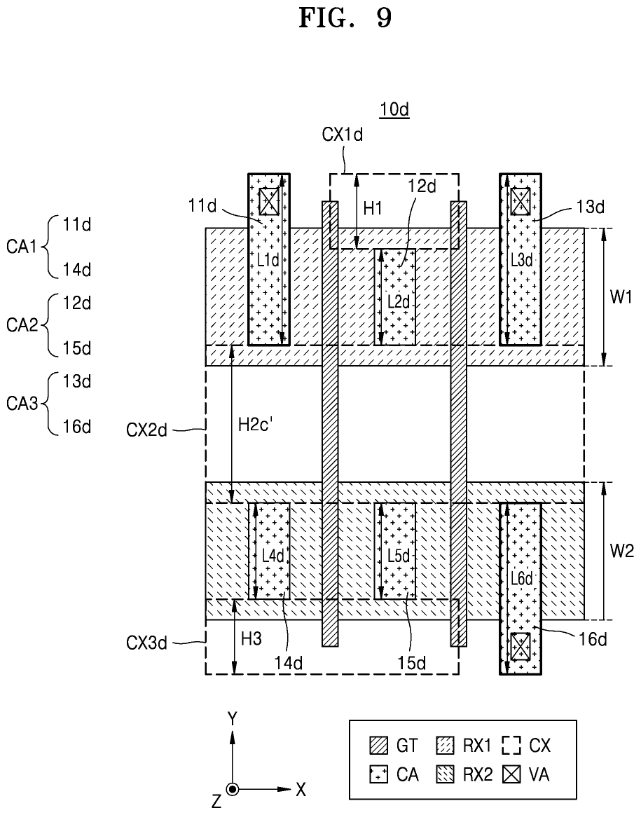

FIG. 9 shows a layout of an integrated circuit 10d according to an embodiment.

Referring to FIG. 9, the integrated circuit 10d corresponds to a modified example of the integrated circuit 10 in FIG. 1, and the descriptions given above with reference to FIGS. 1 to 4E may also apply to the integrated circuit 10d. The first contact CA1 may be divided into first and fourth source/drain contacts 11d and 14d by a second cutting region CX2d. The second contact CA2 may be divided into second and fifth source/drain contacts 12d and 15d by the second cutting region CX2d. The third contact CA3 may be divided into third and sixth source/drain contacts 13d and 16d by the second cutting region CX2d. According to an embodiment, each of the first to third cutting regions CX1d, CX2d, and CX3d may be formed as a rectangle.

The second cutting region CX2d may have a rectangular shape with a second height H2c′ in the second direction Y. Accordingly, a first length L1d of the first source/drain contact 11d may be less than the first length L1 of the first source/drain contact 11 in FIG. 3. Also, a third length L3d of the third source/drain contact 13d may be less than the third length L3 of the third source/drain contact 13 in FIG. 3. Furthermore, a sixth length L6d of the sixth source/drain contact 16d may be less than the sixth length L6 of the sixth source/drain contact 16 in FIG. 3.

As described above with reference to FIGS. 1 to 9, according to embodiments, the length of the source/drain contact and/or the length of the cutting region for cutting the source/drain contact may be adjusted in the integrated circuit, depending on the characteristics of the source/drain contact or the characteristics of the line connected to the source/drain contact. For example, to reduce the resistance of a source/drain contact connected to the power net, the size of the source/drain contact may be increased. For example, to reduce the capacitance of a source/drain contact connected to the signal net, the size of the source/drain contact may be reduced.

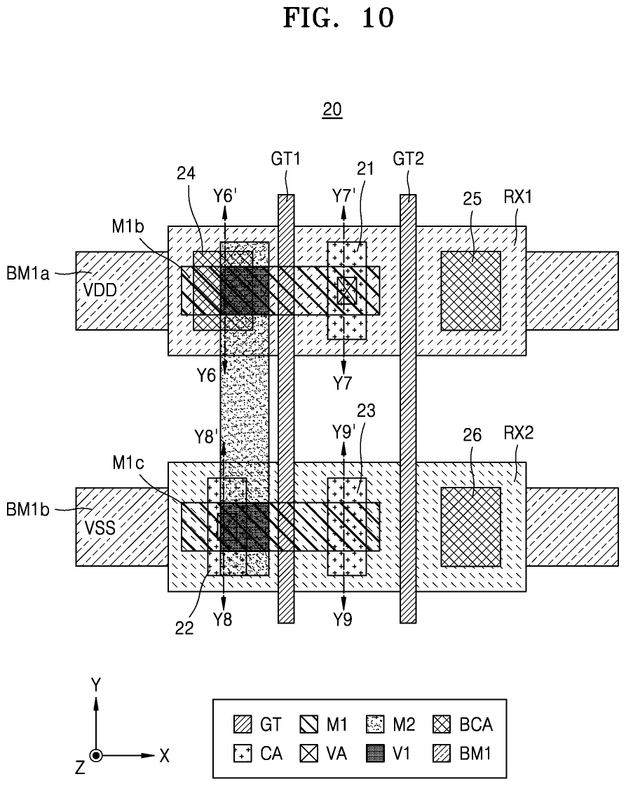

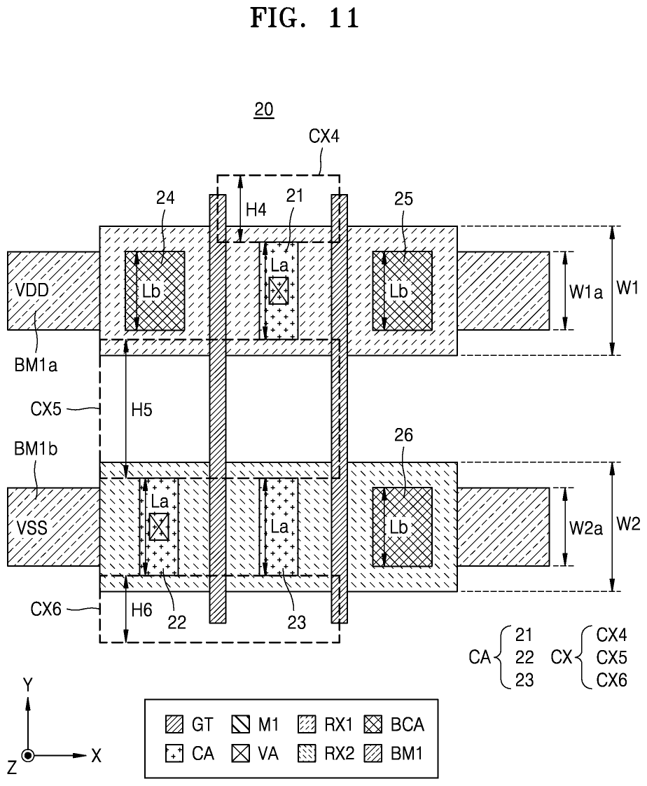

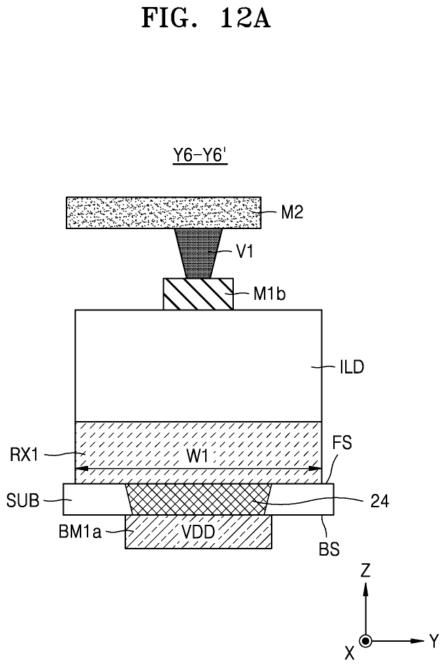

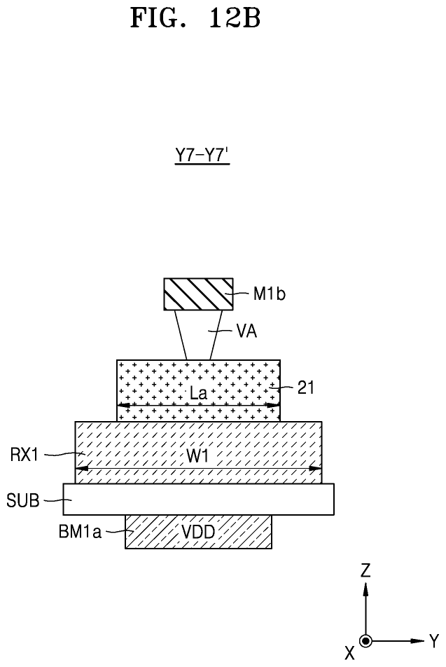

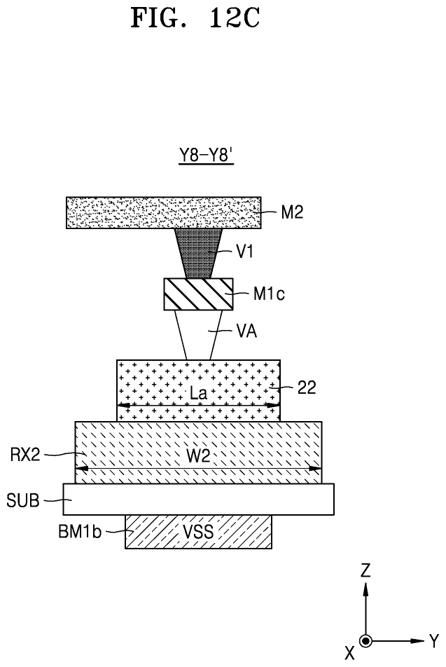

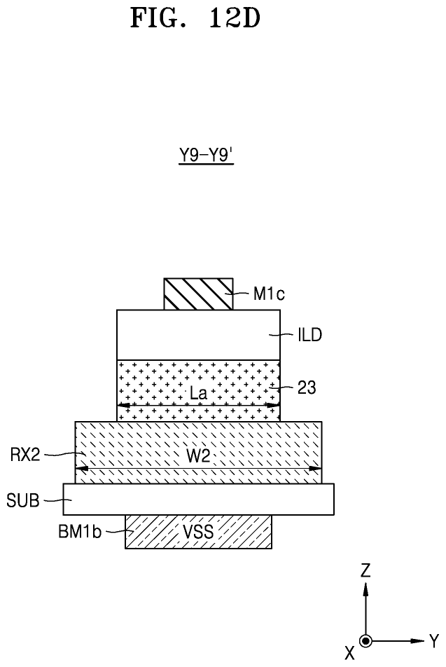

FIG. 10 shows a layout of an integrated circuit 20 according to an embodiment. FIG. 11 shows a portion of the integrated circuit 20 of FIG. 10, according to an embodiment. FIG. 12A is an example of a cross-sectional view of the integrated circuit 20 taken along line Y6-Y6′ in FIG. 10, FIG. 12B is an example of a cross-sectional view of the integrated circuit 20 taken along line Y7-Y7′ in FIG. 10, FIG. 12C is an example of a cross-sectional view of the integrated circuit 20 taken along line Y8-Y8′ in FIG. 10, and FIG. 12D is an example of a cross-sectional view of the integrated circuit 20 taken along line Y9-Y9′ in FIG. 10.

Referring to FIGS. 10 to 12D together, the integrated circuit 20 may include first and second active regions RX1 and RX2, a plurality of source/drain contacts CA, a plurality of backside contacts BCA, a plurality of gate lines GT, a plurality of first vias VA, a plurality of second vias V1, a first wiring layer M1, and a first backside wiring layer BM1. The integrated circuit 20 corresponds to a modified example of the integrated circuit 10 in FIG. 1, and the descriptions given above with reference to FIGS. 1 to 9 may also apply to the integrated circuit 20. For example, the integrated circuit 20 may correspond to an embodiment of the circuit diagram illustrated in FIG. 2.

The integrated circuit 20 may include a front-side wiring layer disposed above a front side FS of a substrate SUB and a backside wiring layer disposed on a backside BS of the substrate SUB, and a power distribution network (PDN) may be implemented by using the front-side wiring layer and the backside wiring layer. Thus, a portion of the signals and/or powers applied to the integrated circuit 20 may be transmitted via the front-side wiring layer, i.e., the front side PDN (FSPDN), and the others may be transmitted via the backside wiring layer, i.e., the backside PDN (BSPDN). Therefore, embodiments may significantly reduce routing complexity compared to a structure in which wires are arranged only on the front side FS of the substrate SUB, and may also reduce the length of each of the wires and each of the vias, thereby improving the performance of the integrated circuit 20.

The first wiring layer M1 may correspond to the front-side wiring layer disposed above the front side FS of the substrate SUB. For example, the first wiring layer M1 may include second and third wiring patterns M1b and M1c each extending in the first direction X. The first backside wiring layer BM1 may correspond to the backside wiring layer disposed on the backside BS of the substrate SUB. For example, the first backside wiring layer BM1 may include first and second backside patterns BM1a and BM1b each extending in the first direction X. For example, the first backside pattern BM1a may have a width W1a in the second direction Y, and the second backside pattern BM1b may have a width W2a in the second direction Y. According to an embodiment, a signal may be transmitted via the front-side wiring layer including the first wiring layer M1, and power may be supplied via the backside wiring layer including the first backside wiring layer BM1.

The plurality of source/drain contacts CA may include first to third source/drain contacts 21 to 23, each of which extends in the second direction Y. The first source/drain contact 21 may be connected to the second wiring pattern M1b via the first via VA, and the second source/drain contact 22 may be connected to the third wiring pattern M1c via the first via VA. The second wiring pattern M1b may be connected to the second wiring layer M2 via the second via V1, and the third wiring pattern M1c may be connected to the second wiring layer M2 via the second via V1. Accordingly, the first and second source/drain contacts 21 and 22 may correspond to the signal net for transmitting the output signal. Also, the third source/drain contact 23 may correspond to, for example, the connection node of the first and second N-type transistors NM1 and NM2 in FIG. 2.

The cutting regions CX may include first to third cutting regions CX4 to CX6. The first cutting region CX4 may have a rectangular shape with a height H4 in the second direction Y, the second cutting region CX5 may have a rectangular shape with a height H5 in the second direction Y, and the third cutting region CX6 may have a rectangular shape with a height H6 in the second direction Y.

For example, the first source/drain contact 21 may extend in the second direction Y, above the first active region RX1, and may have a length La. Accordingly, an overlap region in which the first source/drain contact 21 overlaps the first active region RX1 may have the length La in the second direction Y. For example, the second and third source/drain contacts 22 and 23 may each extend in the second direction Y above the second active region RX2, and the second and third source/drain contacts 22 and 23 may have the same length La in the second direction Y. Accordingly, the overlap regions in which the second and third source/drain contacts 22 and 23 overlap the second active region RX2 may have the same length in the second direction Y.

The plurality of backside contacts BCA may include the first to third backside contacts 24 to 26. In some embodiments, the plurality of backside contacts BCA may be referred to as direct backside contacts (DBCs). For example, each of the first to third backside contacts 24 to 26 may have a length Lb in the second direction Y, but embodiments are not limited thereto. In some embodiments, the first to third backside contacts 24 to 26 may have different sizes. In an embodiment, the first to third backside contacts 24 to 26 may correspond to a power net for supplying power.

For example, the first and second backside contacts 24 and 25 may be disposed on the first backside pattern BM1a and pass through the substrate SUB in the vertical direction Z. Accordingly, the first and second backside contacts 24 and 25 may electrically connect the first backside pattern BM1a to the first active region RX1, and the first active region RX1 may receive the power supply voltage VDD from the first backside pattern BM1a via the first and second backside contacts 24 and 25. For example, the source/drain regions (e.g., the sources of the first and second P-type transistors PM1 and PM2 in FIG. 2) of the first active region RX1 may receive the power supply voltage VDD via the first and second backside contacts 24 and 25.

For example, the third backside contact 26 may be disposed on the second backside pattern BM1b and pass through the substrate SUB in the vertical direction Z. Accordingly, the third backside contact 26 may electrically connect the second backside pattern BM1b to the second active region RX2, and the second active region RX2 may receive the ground voltage VSS from the second backside pattern BM1b via the third backside contact 26. For example, the source/drain region (e.g., the source of the first N-type transistor NM1 in FIG. 2) of the second active region RX2 may receive the ground voltage VSS via the third backside contact 26.

In an embodiment, each of the first and second backside contacts 24 and 25, may have a width in the second direction Y to maximize contact with the first backside pattern BM1a, and the third backside contact 26 may have a width in the second direction Y to maximize contact with the second backside pattern BM1b. For example, each of the first and second backside contacts 24 and 25 may have a width corresponding to the width W1a of the first backside pattern BM1a in the second direction Y. For example, the third backside contact 26 may have a width corresponding to the width W2a of the second backside pattern BM1b in the second direction Y. In an embodiment, each of the first to third backside contacts 24, 25, and 26 may be as wide as possible in the first direction X without interfering with adjacent components (i.e., a without violating a design rule). In an embodiment, by maximizing the widths in the first direction X and the second direction Y, each of the first to third backside contacts 24, 25, and 26 may have an area as large as possible. Accordingly, the resistance of the first to third backside contacts 24, 25, and 26 may be reduced.

The first and second backside patterns BM1a and BM1b may correspond to “power lines.” For example, the first backside pattern BM1a may supply the power supply voltage to the first active region RX1 via the first and second backside contacts 24 and 25. For example, the second backside pattern BM1b may overlap the second active region RX2 and supply the ground voltage to the second active region RX2 via the third backside contact 26. As described above, the IR drop may become an important factor in the case of the supply of power supply voltage or ground voltage. Particularly, as the resistance in a supply path of the power supply voltage or the ground voltage is reduced, the performance of the integrated circuit 20 may be improved. Therefore, the size (for example, width and/or area) of each of the first to third backside contacts 24 to 26 may be formed relatively large, and thus, the supply efficiency of the power supply voltage or the ground voltage may be improved.

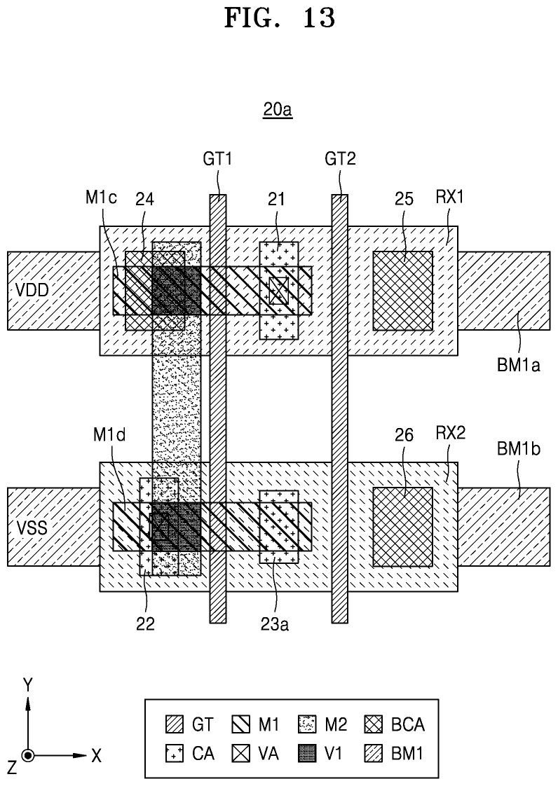

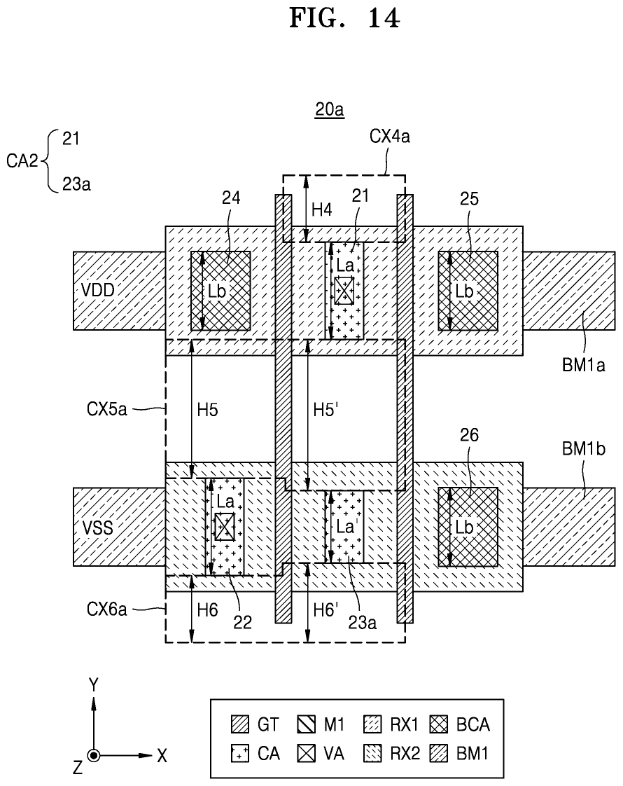

FIG. 13 shows a layout of an integrated circuit 20a according to an embodiment. FIG. 14 shows a portion of the integrated circuit 20a of FIG. 13, according to an embodiment.

Referring to FIGS. 13 and 14 together, the integrated circuit 20a corresponds to a modified example of the integrated circuit 20 in FIG. 10, and the descriptions given above with reference to FIGS. 10 to 12D may also apply to the integrated circuit 20a. The cutting regions CX may include first to third cutting regions CX4a, CX5a, and CX6a. The second contact CA2 may be divided into first and third source/drain contacts 21 and 23a by the second cutting region CX5a. According to an embodiment, the second and third cutting regions CX5a and CX6a may each be formed as a polygon having different lengths in the second direction Y.

The second cutting region CX5a may have a polygonal shape with different lengths in the second direction Y. For example, the second cutting region CX5a may have a height H5′ between portions of the signal net, i.e., between the first and third source/drain contacts 21 and 23a, and have a height H5 between a region adjacent to the first backside contact 24 and the second source/drain contact 22. For example, the height H5′ may be greater than the height H5. The third cutting region CX6a may have the height H6 in the second direction Y in a region adjacent to the second source/drain contact 22 and a height H6′ in the second direction Y in a region adjacent to the third source/drain contact 23a. For example, the height H6′ may be greater than the height H6, and thus, the third source/drain contact 23a may have a shorter length than the third source/drain contact 23 in FIG. 10.

Particularly, the third source/drain contact 23a may be configured such that the upper edge thereof is located inside the second active region RX2 by the second cutting region CX5a and the lower edge thereof is located inside the second active region RX2 by the third cutting region CX6a. Thus, the third source/drain contact 23a may have a length La′ in the second direction Y, and the length of a region in which the third source/drain contact 23a overlaps the second active region RX2 may correspond to the length La'. In this case, the length La′ may be less than the length La in FIG. 10, and thus, the capacitance of the third source/drain contact 23a may be further reduced. Therefore, the RC delay of the signal transmitted via the third source/drain contact 23a may be further improved.

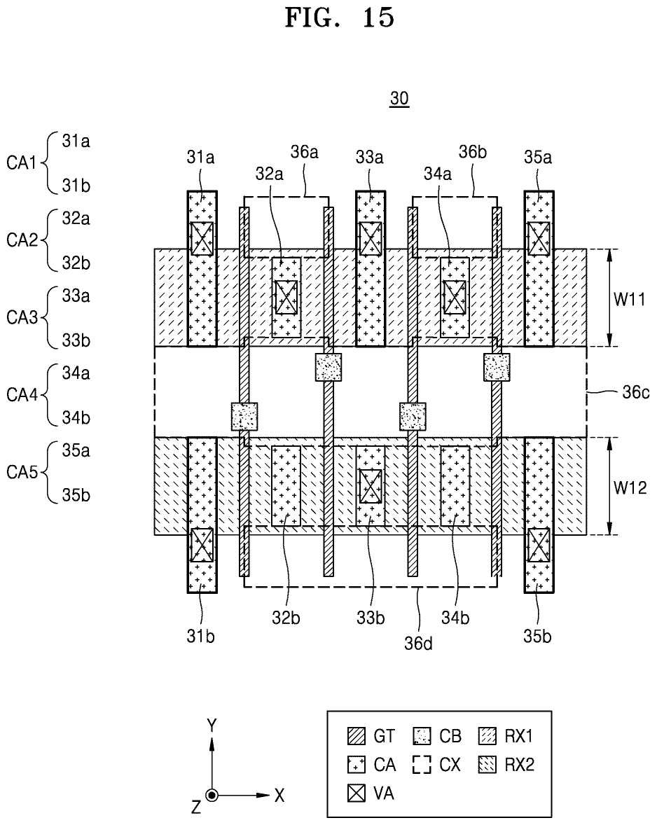

FIG. 15 shows a layout of a single height cell 30 according to an embodiment.

Referring to FIG. 15, the single height cell 30 may include first and second active regions RX1 and RX2, a plurality of source/drain contacts CA, a plurality of gate lines GT, a plurality of gate contacts CB, and a plurality of first vias VA. The single height cell 30 may be defined by a cell boundary. The descriptions given above with reference to FIGS. 1 to 14 may also apply to the single height cell 30, and repeated descriptions thereof are omitted.

A plurality of source/drain contacts CA may each extend in the second direction Y. The cutting regions CX may include first to fourth cutting regions 36a to 36d. A first contact CA1 may be divided into source/drain contacts 31a and 31b by the third cutting region 36c. A second contact CA2 may be divided into source/drain contacts 32a and 32b by the third cutting region 36c. A third contact CA3 may be divided into source/drain contacts 33a and 33b by the third cutting region 36c. A fourth contact CA4 may be divided into source/drain contacts 34a and 34b by the third cutting region 36c. A fifth contact CA5 may

### Be Divided Into Source/drain Contacts 35a and 35b by the Third Cutting Region 36c.

In an embodiment, the source/drain contacts 31a, 31b, 33a, 35a, and 35b may correspond to power nets for supplying the power supply voltage or the ground voltage and may be thus referred to as power contacts 31a, 31b, 33a, 35a, and 35b. In an embodiment, the source/drain contacts 32a, 32b, 33b, 34a, and 34b may correspond to signal nets for transmitting signals and may be thus referred to as signal contacts 32a, 32b, 33b, 34a, and 34b. In FIG. 15, the outlines of the power contacts 31a, 31b, 33a, 35a, and 35b are shown thicker than the outlines of the signal contacts 32a, 32b, 33b, 34a, and 34b.

The first, second, and fourth cutting regions 36a, 36b, and 36d may each have a rectangular shape with a constant height in the second direction Y. Also, the third cutting region 36c may have a polygonal shape with different heights in the second direction Y. Accordingly, the length of each of the power contacts 31a, 31b, 33a, 35a, and 35b may be greater than the length of each of the signal contacts 32a, 32b, 33b, 34a, and 34b.

The length along which each of the power contacts 31a, 33a, and 35a is in contact with the first active region RX1 may correspond to a first width W11 (for example, an overlap region between each of the power contacts 31a, 33a, and 35a and the first active region RX1 may have a length corresponding to the first width W11 in the second direction Y), and the length along which each of the power contacts 31b and 35b is in contact with the second active region RX2 may correspond to a second width W12 (for example, an overlap region between each of the power contacts 31b and 35b and the second active region RX2 may have a length corresponding to the second width W12 in the second direction Y). As described above, the sizes of the power contacts 31a, 31b, 33a, 35a, and 35b may be increased to reduce the resistance of the power contacts 31a, 31b, 33a, 35a, and 35b. Accordingly, the power supply efficiency may be improved, and thus, the performance of the single height cell 30 may be enhanced.

Also, the length along which each of the signal contacts 32a and 34a is in contact with the first active region RX1 may be less than the first width W11 (for example, an overlap region between each of the signal contacts 32a and 34a and the first active region RX1 may have a length less than the first width W11 in the second direction Y), and the length along which each of the signal contacts 32b, 33b, and 34b is in contact with the second active region RX2 may be less than the second width W12 (for example, an overlap region between each of the signal contacts 32b, 33b, and 34b and the second active region RX2 may have a length less than the second width W12 in the second direction Y). As described above, the sizes of the signal contacts 32a, 32b, 33b, 34a, and 34b may be reduced to decrease the capacitance of the signal contacts 32a, 32b, 33b, 34a, and 34b. Accordingly, the signal transmission efficiency may be improved, and thus, the performance of the single height cell 30 may be enhanced.

FIG. 16 shows a layout of a first double height cell 40 according to an embodiment.

Referring to FIG. 16, the first double height cell 40 may include first to third active regions RX1, RX2, and RX3, a plurality of source/drain contacts CA, a plurality of gate lines GT, a plurality of gate contacts CB, and a plurality of first vias VA. The first double height cell 40 may be defined by a cell boundary. The descriptions given above with reference to FIGS. 1 to 14 may also apply to the first double height cell 40, and repeated descriptions thereof are omitted.

A plurality of source/drain contacts CA may each extend in the second direction Y. The cutting regions CX may include first to sixth cutting regions 46a to 46f. A first contact CA1 may be divided into source/drain contacts 41a, 41b, and 41c by the third and fourth cutting regions 46c and 46d. A second contact CA2 may be divided into source/drain contacts 42a, 42b, and 42c by the third and fourth cutting regions 46c and 46d. A third contact CA3 may be divided into source/drain contacts 43a, 43b, and 43c by the third and fourth cutting regions 46c and 46d. A fourth contact CA4 may be divided into source/drain contacts 44a, 44b, and 44c by the third and fourth cutting regions 46c and 46d. A fifth contact CA5 may be divided into source/drain contacts 45a, 45b, and 45c by the third and fourth cutting regions 46c and 46d.

In an embodiment, the source/drain contacts 41a, 41b, 41c, 43a, 43b, 43c, 45a, 45b, and 45c may correspond to power nets for supplying the power supply voltage or the ground voltage and may be thus referred to as power contacts 41a, 41b, 41c, 43a, 43b, 43c, 45a, 45b, and 45c. In an embodiment, the source/drain contacts 42a, 42b, 42c, 44a, 44b, and 44c may correspond to signal nets for transmitting signals and may be thus referred to as signal contacts 42a, 42b, 42c, 44a, 44b, and 44c. In FIG. 16, the outlines of the power contacts 41a, 41b, 41c, 43a, 43b, 43c, 45a, 45b, and 45c are shown thicker than the outlines of the signal contacts 42a, 42b, 42c, 44a, 44b, and 44c.

The first, second, fifth, and sixth cutting regions 46a, 46b, 46e, and 46f may each have a rectangular shape with a constant height in the second direction Y. Also, the third and fourth cutting regions 46c and 46d may each have a polygonal shape with different heights in the second direction Y. Accordingly, the length of each of the power contacts 41a, 41b, 41c, 43a, 43b, 43c, 45a, 45b, and 45c may be greater than the length of each of the signal contacts 42a, 42c, 44a, and 44c.

The length along which each of the power contacts 41a, 43a, and 45a is in contact with the first active region RX1 may correspond to a first width W21 (for example, an overlap region between each of the power contacts 41a, 43a, and 45a and the first active region RX1 may have a length correspond to the first width W21 in the second direction Y), the length along which each of the power contacts 41b, 43b, and 45b is in contact with the second active region RX2 may correspond to a second width W22 (for example, an overlap region between each of the power contacts 41b, 43b, and 45b and the second active region RX2 may have a length correspond to the second width W22 in the second direction Y), and the length along which each of the power contacts 41c, 43c, and 45c is in contact with the third active region RX3 may correspond to a third width W23 (for example, an overlap region between each of the power contacts 41c, 43c, and 45c and the third active region RX3 may have a length correspond to the third width W23 in the second direction Y). As described above, the sizes of the power contacts 41a, 41b, 41c, 43a, 43b, 43c, 45a, 45b, and 45c may be increased to reduce the resistance of the power contacts 41a, 41b, 41c, 43a, 43b, 43c, 45a, 45b, and 45c. Accordingly, the power supply efficiency may be improved, and thus, the performance of the first double height cell 40 may be enhanced.

The first via VA may be disposed on each of the power contacts 41a, 41b, 41c, 43a, 43b, 43c, 45a, 45b, and 45c. In an embodiment, the first via VA on each of the power contacts 41a, 41b, 41c, 43a, 43b, 43c, 45a, 45b, and 45c may be formed as a “large via” extending in the second direction Y. In an embodiment, two or more first vias VA may be disposed on each of the power contacts 41a, 41b, 41c, 43a, 43b, 43c, 45a, 45b, and 45c, and the two or more first vias VA may be formed into a single large via by a via retarget layer during a process. The first via VA on each of the power contacts 41a, 41b, 41c, 43a, 43b, 43c, 45a, 45b, and 45c may be referred to as a “power via.” Also, the length along which each of the signal contacts 42a and 44a is in contact with the first active region RX1 may be less than the first width W21 (for example, an overlap region between each of the signal contacts 42a and 44a and the first active region RX1 may have a length less than the first width W21 in the second direction Y), the length along which each of the signal contacts 42b and 44b is in contact with the second active region RX2 may be less than the second width W22 (for example, an overlap region between each of the signal contacts 42b and 44b and the second active region RX2 may have a length less than the second width W22 in the second direction Y), and the length along which each of the signal contacts 42c and 44c is in contact with the third active region RX3 may be less than the third width W23 (for example, an overlap region between each of the signal contacts 42c and 44c and the third active region RX3 may have a length less than the third width W23 in the second direction Y). As described above, the size of the region that overlaps the active region corresponding to each of the signal contacts 42a, 42b, 42c, 44a, 44b, and 44c may be reduced, and thus, the capacitance of the signal contacts 42a, 42b, 42c, 44a, 44b, and 44c may be reduced. Accordingly, the signal transmission efficiency may be improved, and thus, the performance of the first double height cell 40 may be enhanced.

The first via VA may be disposed on each of the signal contacts 42a, 42b, 42c, 44a, 44b, and 44c. The first via VA on each of the signal contacts 42a, 42b, 42c, 44a, 44b, and 44c may be referred to as a “signal via.” In an embodiment, the length of each signal via in the second direction Y may be less than the length of each power via in the second direction Y. However, embodiments are not limited thereto.

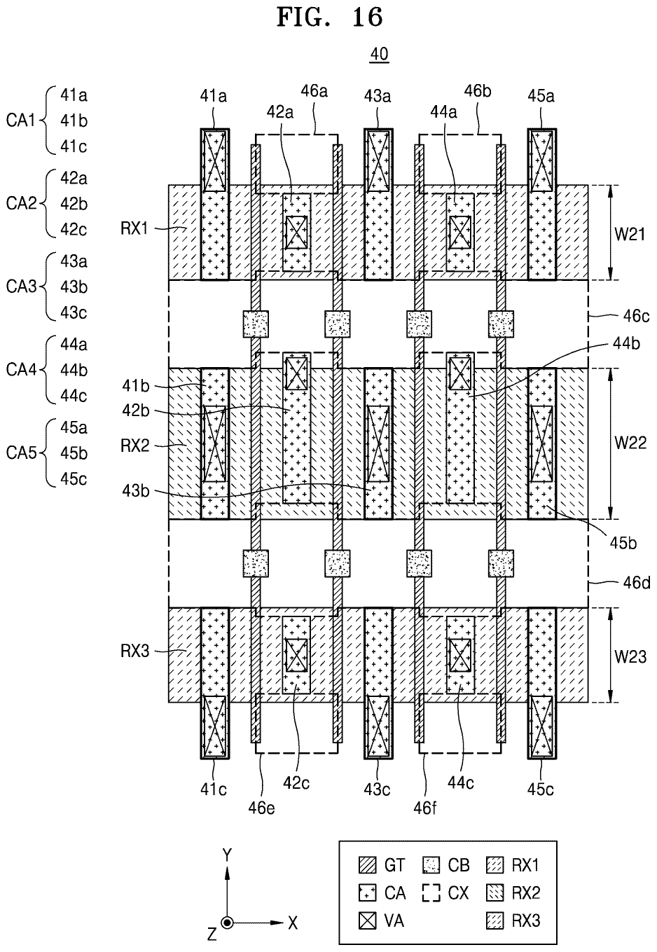

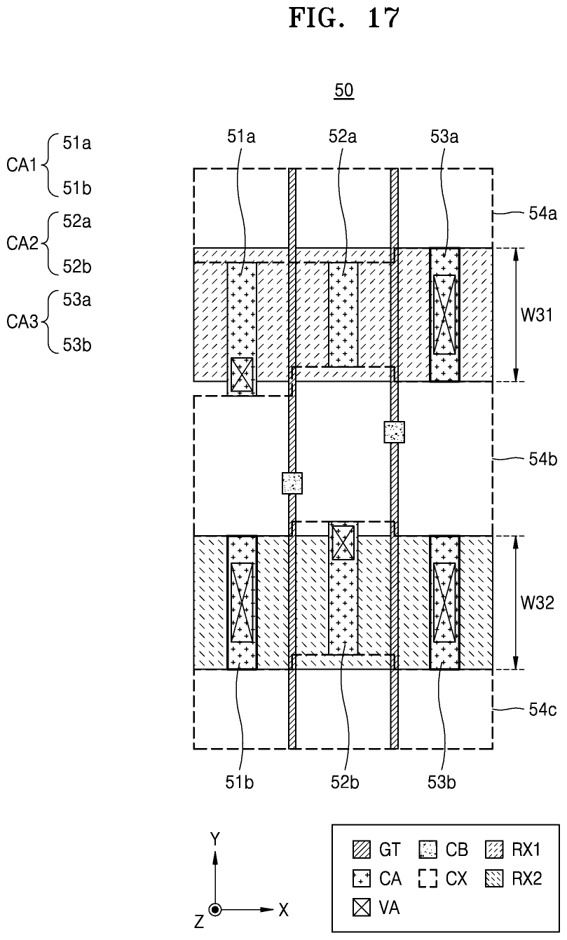

FIG. 17 shows a layout of a second double height cell 50 according to an embodiment.

Referring to FIG. 17, the second double height cell 50 may include first and second active regions RX1 and RX2, a plurality of source/drain contacts CA, a plurality of gate lines GT, a plurality of gate contacts CB, and a plurality of first vias VA. The second double height cell 50 may be defined by a cell boundary. The descriptions given above with reference to FIGS. 1 to 14 may also apply to the second double height cell 50, and repeated descriptions thereof are omitted.

A plurality of source/drain contacts CA may each extend in the second direction Y. The cutting regions CX may include first to third cutting regions 54a to 54c. A first contact CA1 may be divided into source/drain contacts 51a and 51b by the second cutting region 54b. A second contact CA2 may be divided into source/drain contacts 52a and 52b by the second cutting region 54b. A third contact CA3 may be divided into source/drain contacts 53a and 53b by the second cutting region 54b.

In an embodiment, the source/drain contacts 53a, 51b, and 53b may correspond to power nets for supplying the power supply voltage or the ground voltage and may be thus referred to as power contacts 53a, 51b, and 53b. In an embodiment, the source/drain contacts 51a, 52a, and 52b may correspond to signal nets for transmitting signals and may be thus referred to as signal contacts 51a, 52a, and 52b. In FIG. 17, the outlines of the power contacts 53a, 51b, and 53b are shown thicker than the outlines of the signal contacts 51a, 52a, and 52b.

The first, second, and third cutting regions 54a, 54b, and 54c may have polygonal shapes with different heights in the second direction Y. Accordingly, the length of each of the power contacts 53a, 51b, and 53b may be greater than the length of the signal contact 52a. The length along which the power contact 53a is in contact with the first active region RX1 may correspond to a first width W31 (for example, an overlap region between the power contact 53a and the first active region RX1 may have a length correspond to the first width W31 in the second direction Y), and the length along which each of the power contacts 51b and 53b is in contact with the second active region RX2 may correspond to a second width W32 (for example, an overlap region between each of the power contacts 51b and 53b and the second active region RX2 may have a length correspond to the second width W32 in the second direction Y). As described above, the size of the power contacts 53a, 51b, and 53b may be increased to reduce the resistance of the power contacts 53a, 51b, and 53b. Accordingly, the power supply efficiency may be improved, and thus, the performance of the second double height cell 50 may be enhanced.

A first via VA may be disposed on each of the power contacts 53a, 51b, and 53b. In an embodiment, the first via VA on each of the power contacts 53a, 51b, and 53b may be formed as a “large via” extending in the second direction Y. In an embodiment, two or more first vias VA may be disposed on each of the power contacts 53a, 51b, and 53b, and the two or more first vias VA may be formed into a single large via by a via retarget layer during a process. The first via VA on each of the power contacts 53a, 51b, and 53b may be referred to as a “power via.”

Also, the length along which each of the signal contacts 51a and 52a is in contact with the first active region RX1 may be less than the first width W31 (for example, an overlap region between each of the signal contacts 51a and 52a and the first active region RX1 may have a length less than the first width W31 in the second direction Y), and the length along which the signal contact 52b is in contact with the second active region RX2 may be less than the second width W32 (for example, an overlap region between the signal contact 52b and the second active region RX2 may have a length less than the second width W32 in the second direction Y). As described above, the size of the region that overlaps the active region corresponding to each of the signal contacts 51a, 52a, and 52b may be reduced, and thus, the capacitance of the signal contacts 51a, 52a, and 52b may be reduced. Accordingly, the signal transmission performance may be improved, and thus, the performance of the second double height cell 50 may be enhanced.

The first via VA may be disposed on each of the signal contacts 51a and 52b. The first via VA on the signal contacts 51a and 52b may be referred to as a “signal via.” In an embodiment, the length of each signal via in the second direction Y may be less than the length of each power via in the second direction Y. However, embodiments are not limited thereto.

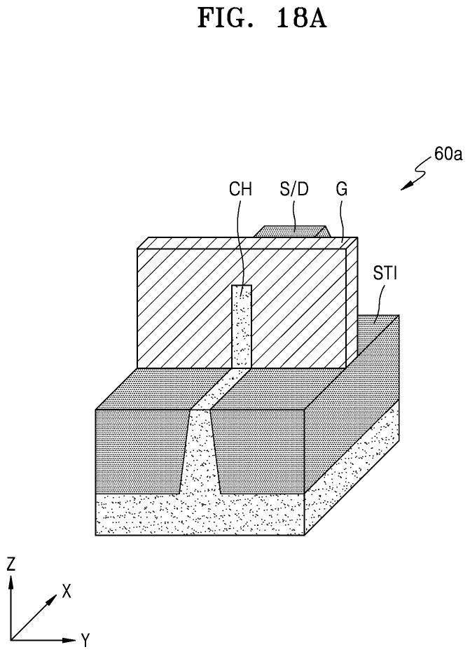

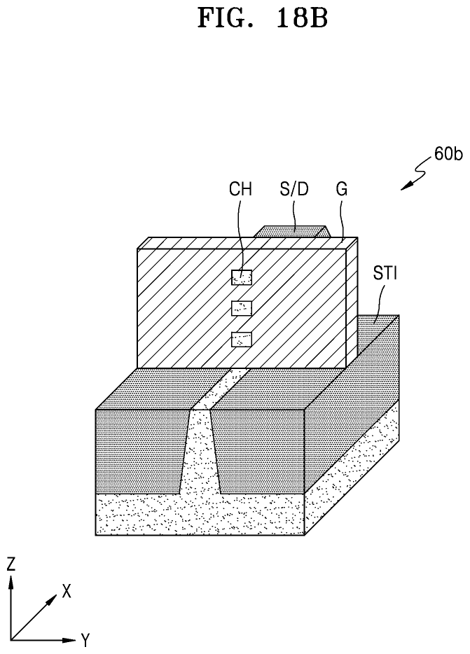

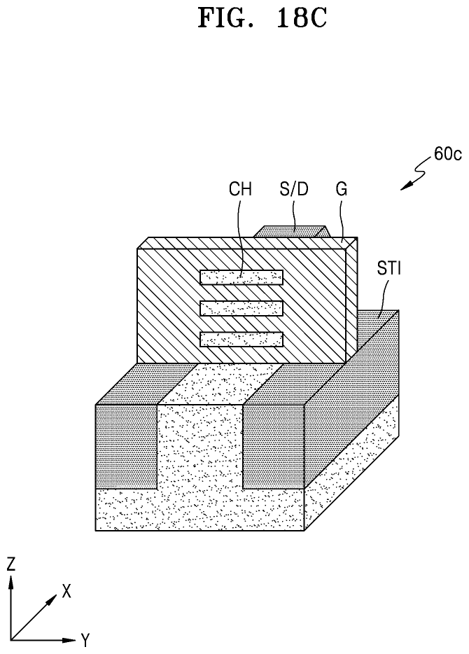

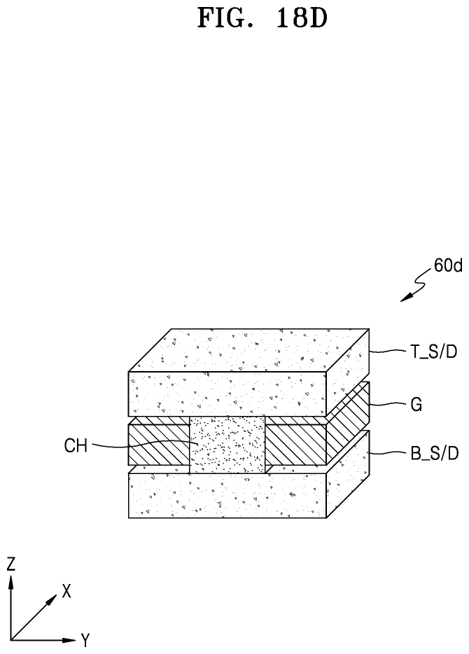

FIGS. 18A to 18D each show a device according to some embodiments.

For example, FIG. 18A shows a fin field effect transistor (FinFET) 60a, FIG. 18B shows a GAAFET 60b, FIG. 18C shows a multi-bridge channel field effect transistor (MBCFET) 60c, and FIG. 18D shows a vertical field effect transistor (VFET) 60d. For convenience of illustration, FIGS. 18A to 18C each illustrate a state in which one of source/drain regions is removed, and FIG. 18D illustrates a cross-section of the VFET 60d taken along a plane that is parallel to the plane formed by the second direction Y and the vertical direction Z and passing through a channel CH of the VFET 60d.

Referring to FIG. 18A, the FinFET 60a may be formed by an active pattern that has a fin shape extending in the first direction X between shallow trench isolations STI and a gate G that extends in the second direction Y. Source/drain regions S/D may be formed on both sides of the gate G, and thus, source/drain pairs may be spaced apart from each other in the first direction X. A gate insulating layer (e.g., GI in FIG. 4E) may be formed between the channel CH and the gate G. In some embodiments, the FinFET 60a may be formed by the gate G and the plurality of active patterns which are spaced apart from each other in the second direction Y.

Referring to FIG. 18B, the GAAFET 60 b may be formed by active patterns, i.e., nanowires, each extending in the first direction X and spaced apart from each other in the vertical direction Z, and a gate G extending in the second direction Y. Source/drain regions S/D may be formed on both sides of the gate G, and thus, source/drain pairs may be spaced apart from each other in the first direction X. A gate insulating layer (e.g., GI in FIG. 4E) may be formed between the channel CH and the gate G. It is noted that the number of nanowires in the GAAFET 60b is not limited to that shown in FIG. 18B.

Referring to FIG. 18C, the MBCFET 60c may be formed by active patterns, i.e., nanosheets, each extending in the first direction X and spaced apart from each other in the vertical direction Z, and a gate G extending in the second direction Y. Source/drain regions S/D may be formed on both sides of the gate G, and thus, source/drain pairs may be spaced apart from each other in the first direction X. A gate insulating layer (e.g., GI in FIG. 4E) may be formed between the channel CH and the gate G. It is noted that the number of nanosheets in the MBCFET 60c is not limited to that shown in FIG. 18C.

Referring to FIG. 18D, the VFET 60d may include a top source/drain region T_S/D and a bottom source/drain region B_S/D, which are spaced apart from each other in the vertical direction Z with a channel CH therebetween. The VFET 60d may include a gate G that surrounds a channel CH between the top source/drain region T_S/D and the bottom source/drain region B_S/D. A gate insulating layer (e.g., GI in FIG. 4E) may be formed between the channel CH and the gate G.

The integrated circuit according to embodiments may include a plurality of cells, and each of the cells may include various transistors as illustrated in FIGS. 18A to 18D. However, the transistors according to embodiments are not limited to the structures described above. For example, the integrated circuit may include a ForkFET in which a dielectric wall isolates nanosheets for a P-type transistor from nanosheets for an N-type transistor, thereby forming a structure in which the N-type transistor is closer to the P-type transistor. In addition, the integrated circuit may include not only FETs, such as a complementary FET (CFET), a negative CFET (NCFET), and a carbon nanotube FET (CNT FET), but also bipolar junction transistors.

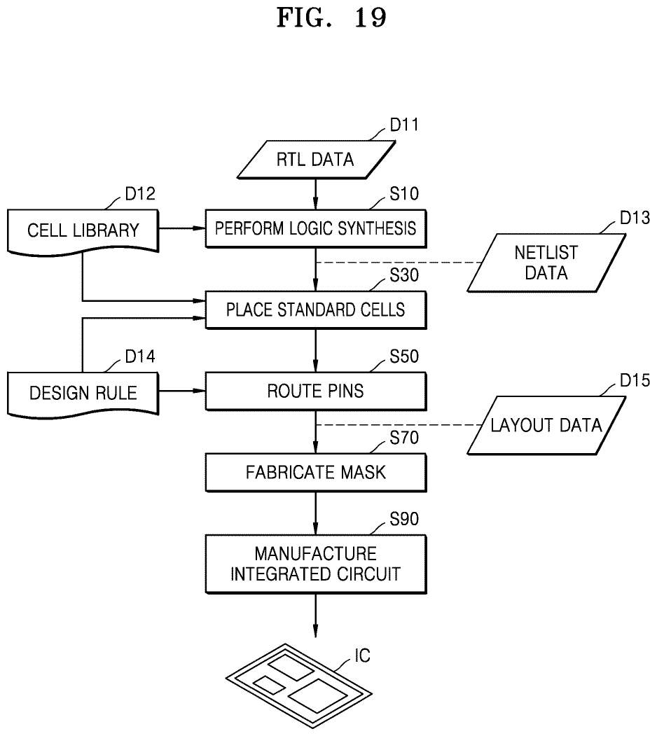

FIG. 19 is a flowchart showing a method of manufacturing an integrated circuit, according to an embodiment.

Referring to FIG. 19, the method according to an embodiment may provide a method of manufacturing an integrated circuit IC including standard cells and may include a plurality of operations S10, S30, S50, S70, and S90. A cell library (or a standard cell library) D12 may include information about standard cells, such as information about functions, characteristics, layouts, etc. In some embodiments, the cell library D12 may define not only function cells that generate output signals from input signals, but also tap cells, filler cells, and dummy cells. For example, the cell library D12 may define standard cells that include source/drain contacts having different lengths depending on the characteristics of corresponding nets. A design rule D14 may include requirements that a layout of the integrated circuit IC has to comply with. For example, the design rule D14 may include requirements for the space between patterns in the same layer, the minimum width of a pattern, the routing direction in a wiring layer, etc.

In operation S10, a logic synthesis operation of generating netlist data D13 from register-transfer level (RTL) data D11 may be performed. For example, a semiconductor design tool (e.g., a logic synthesis tool) may perform logic synthesis with reference to the cell library D12 from the RTL data D11 written as a hardware description language (HDL), such as very high-speed integrated circuit (VHSIC) hardware description language (VHDL) and Verilog, and may generate the netlist data D13 including a bitstream or netlist. The Netlist data D13 may correspond to input of placement and routing (or referred to as P&R) described below.

In operation S30, standard cells may be placed. For example, the semiconductor design tool (e.g., a P&R tool) may place the standard cells used in the netlist data D13, with reference to the cell library D12. In some embodiments, the semiconductor design tool may place standard cells in rows that extend in the X-axis direction or the Y-axis direction, and the placed standard cells may be supplied with power from power rails that extend along boundaries of the rows.

In operation S50, pins of the standard cells may be routed. For example, the semiconductor design tool may generate interconnections that electrically connect output pins to input pins in the placed standard cells and my generate layout data D15 that defines the placed standard cells and the generated interconnections. The interconnection may include vias in a via layer and/or patterns in wiring layers. The wiring layers may include a front-side wiring layer disposed on the front side of a substrate and a backside wiring layer disposed on the backside of the substrate. The semiconductor design tool may refer to the design rule D14 while routing the pins of cells. The layout data D15 may correspond to the output of P&R. Operation S50 alone or operations S30 and S50 collectively may be referred to as a method of designing the integrated circuit IC.

According to an embodiment, the standard cells may include source/drain contacts or power contacts corresponding to the power net, and source/drain contacts or signal contacts corresponding to the signal net. In this case, the lengths of the power contacts may differ from the lengths of the signal contacts. The length of the region overlapping or in contact with the active region corresponding to each of the power contacts may be greater than the length of the region overlapping or in contact with the active region corresponding to each of the signal contacts. Accordingly, the resistance between the power contact and the active region may be reduced, and the supply efficiency of the power supply voltage or the ground voltage supplied via the power contact may be improved. In addition, the capacitance between the signal contact and the gate line adjacent thereto may be reduced, and the transmission efficiency of the signal transmitted via the signal contact may be improved.

In operation S70, an operation of fabricating a mask may be performed. For example, optical proximity correction (OPC) for correcting distortion phenomena, such as refraction caused by the characteristics of light in photolithography, may be applied to the layout data D15. Patterns on a mask may be defined to form patterns arranged in a plurality of layers on the basis of data to which the OPC is applied, and at least one mask may be fabricated to form the patterns of each of the plurality of layers.

In operation S90, an operation of manufacturing the integrated circuit IC may be performed. For example, the integrated circuit IC may be manufactured by patterning the plurality of layers using the at least one mask which has been fabricated in operation S70. A front-end-of-line (FEOL) may include, for example, planarizing and cleaning a wafer, forming a trench, forming a well, forming a gate line, and forming a source and a drain. By the FEOL, individual devices, such as transistors, capacitors, and resistors, may be formed on a substrate. Also, a back-end-of-line (BEOL) may include, for example, performing silicidation on gate, source and drain regions, adding a dielectric, performing planarization, forming a hole, adding a metal layer, forming a via, forming a passivation layer, etc. By the BEOL, individual devices, such as transistors, capacitors, and resistors, may be connected to each other. In some embodiments, a middle-of-line (MOL) may be performed between the FEOL and BEOL, and contacts may be formed on the individual devices. Next, the integrated circuit IC may be packaged into a semiconductor package and used as a component in a variety of applications.

While aspects of embodiments have been particularly shown and described, it will be understood that various changes in form and details may be made therein without departing from the spirit and scope of the following claims.

What is claimed is:

1. An integrated circuit comprising:
a first active region extending in a first direction on a substrate, wherein the first active region has a first width in a second direction, and the second direction intersects the first direction;
a first source/drain contact extending in the second direction above the first active region, wherein the first source/drain contact is connected to a power line for supplying power, and has a first length in the second direction;
a second source/drain contact extending in the second direction above the first active region, wherein the second source/drain contact is connected to a signal line for transmitting a signal, and has a second length in the second direction; and
a first gate line extending in the second direction between the first source/drain contact and the second source/drain contact,
wherein a length in the second direction of a first overlap region between the first source/drain contact and the first active region is greater than a length in the second direction of a second overlap region between the second source/drain contact and the first active region.

2. The integrated circuit of claim 1, wherein the first length of the first source/drain contact is greater than the second length of the second source/drain contact,
wherein the length of the first overlap region corresponds to the first width of the first active region, and
wherein the length of the second overlap region is less than the first width of the first active region.

3. The integrated circuit of claim 1, further comprising:
a third source/drain contact extending in the second direction above the first active region, wherein the third source/drain contact is connected to the power line; and
a second gate line extending in the second direction between the second source/drain contact and the third source/drain contact,
wherein a length in the second direction of a third overlap region between the third source/drain contact and the first active region is greater than the length of the second overlap region between the second source/drain contact and the first active region.

4. The integrated circuit of claim 1, further comprising:
a second active region extending in the first direction on the substrate, wherein the second active region is spaced apart from the first active region in the second direction; and
a fourth source/drain contact extending in the second direction above the second active region, wherein the fourth source/drain contact has a fourth length in the second direction,
wherein the fourth length of the fourth source/drain contact is less than or equal to the second length of the second source/drain contact.

5. The integrated circuit of claim 4, further comprising a first via disposed only on the second source/drain contact among the second and fourth source/drain contacts, and connecting the second source/drain contact to the signal line.

6. The integrated circuit of claim 4, further comprising a fifth source/drain contact extending in the second direction above the second active region, wherein the fifth source/drain contact is connected to the signal line, and has a fifth length in the second direction,
wherein the fifth length of the fifth source/drain contact is equal to the second length of the second source/drain contact.

7. The integrated circuit of claim 1, further comprising:
a fourth source/drain contact extending in the second direction; and
a first via disposed only on the second source/drain contact among the second and fourth source/drain contacts, wherein the first via connects the second source/drain contact to the signal line,
wherein the fourth source/drain contact has a fourth length in the second direction that is less than or equal to the second length of the second source/drain contact.

8. The integrated circuit of claim 1, further comprising a first wiring layer above a front side of the substrate,
wherein the first wiring layer comprises:
a first wiring pattern corresponding to the power line; and
a second wiring pattern corresponding to the signal line.

9. The integrated circuit of claim 1, further comprising a nanosheet stack comprising a plurality of nanosheets stacked in a vertical direction with respect to the substrate,
wherein the nanosheet stack and the first gate line constitute a gate-all-around (GAA) transistor.

10. An integrated circuit comprising:
a first active region extending in a first direction on a substrate, wherein the first active region has having a first width in a second direction intersecting the first direction;
a front-side wiring layer above a front side of the substrate, wherein the front-side wiring layer comprises a signal line for transmitting a signal;
a backside wiring layer on a backside of the substrate, wherein the backside wiring layer comprises a power line for supplying power;
a first source/drain contact extending in the second direction above the first active region, wherein the first source/drain contact is connected to the signal line, and has a first length less than the first width of the first active region in the second direction; and
a backside contact on the power line, wherein the backside contact passes through the substrate in a vertical direction, is connected to the first active region, and has a second length in the second direction,
wherein a length in the second direction of a first overlap region between the first active region and the first source/drain contact is less than the first width of the first active region.

11. The integrated circuit of claim 10, wherein the power line extends in the first direction and has a second width in the second direction, and
wherein the second length of the backside contact corresponds to the second width of the power line.

12. The integrated circuit of claim 10, further comprising:
a second active region extending in the first direction on the substrate, wherein the second active region is spaced apart from the first active region in the second direction; and
a second source/drain contact extending in the second direction above the second active region, wherein the second source/drain contact has a third length in the second direction,
wherein the third length of the second source/drain contact is less than or equal to the first length of the first source/drain contact.

13. The integrated circuit of claim 12, further comprising a first via disposed only on the first source/drain contact among the first and second source/drain contacts, wherein the first via connects the first source/drain contact to the signal line.

14. The integrated circuit of claim 12, further comprising a third source/drain contact extending in the second direction above the second active region, wherein the third source/drain contact is connected to the signal line, and has a fourth length in the second direction,
wherein the fourth length of the third source/drain contact is equal to the first length of the first source/drain contact.

15. The integrated circuit of claim 10, further comprising:
a gate line extending in the second direction between the first source/drain contact and the backside contact; and
a nanosheet stack comprising a plurality of nanosheets stacked in the vertical direction,
wherein the nanosheet stack and the gate line constitute a gate-all-around (GAA) transistor.

16. An integrated circuit comprising:
a first active region extending in a first direction on a substrate;
a second active region extending in the first direction on the substrate, wherein the second active region is spaced apart from the first active region in a second direction, and the second direction intersects the first direction;
a first source/drain contact extending in the second direction above the first active region, wherein the first source/drain contact is connected to a power line for supplying power, and has a first length in the second direction;
a second source/drain contact extending in the second direction above the first active region, wherein the second source/drain contact is connected to a signal line for transmitting a signal, and has a second length in the second direction;
a third source/drain contact extending in the second direction above the second active region, wherein the third source/drain contact has a third length in the second direction; and
a via disposed only on the second source/drain contact among the second and third source/drain contacts, wherein the via connects the second source/drain contact to the signal line,
wherein a length in the second direction of a first overlap region between the first source/drain contact and the first active region is greater than a length in the second direction of a second overlap region between the second source/drain contact and the first active region.

17. The integrated circuit of claim 16, wherein the length of the second overlap region is greater than a length in the second direction of a third overlap region between the third source/drain contact and the second active region.

18. The integrated circuit of claim 16, further comprising a first wiring layer above the first to third source/drain contacts,
wherein the first wiring layer comprises:
a first wiring pattern corresponding to the power line; and
a second wiring pattern corresponding to the signal line, and
wherein the second length of the second source/drain contact is less than the first length of the first source/drain contact.

19. The integrated circuit of claim 16, further comprising:
a backside wiring layer on a backside of the substrate, wherein the backside wiring layer comprises the power line;
a front-side wiring layer above a front side of the substrate, wherein the front-side wiring layer comprises the signal line; and
a backside contact on the power line and passing through the substrate in a vertical direction,
wherein the power line extends in the first direction and has a first width in the second direction, and
wherein the backside contact has a length in the second direction corresponding to the first width of the power line.

20. The integrated circuit of claim 16, further comprising:
a gate line extending in the second direction between the first source/drain contact and the second source/drain contact; and
a nanosheet stack comprising a plurality of nanosheets stacked in a vertical direction with respect to the substrate,
wherein the nanosheet stack and the gate line constitute a gate-all-around (GAA) transistor.
